(19) United States
(12) Patent Application Publication
(10) Pub. No.: US 2009/0272434 A1
(43) Pub. Date: Nov. 5, 2009

(54) THIN-FILM SOLAR CELL AND METHOD OF FABRICATING THIN-FILM SOLAR CELL

(76) Inventor: Shinsuke Tachibana, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/446,699

(22) PCT Filed: Sep. 19, 2007
(86) PCT No.: PCT/JP2007/068137

§ 371 Date: Apr. 22, 2009

(30) Foreign Application Priority Data
Oct. 27, 2006 (JP) 2006-292685

(51) Int. Cl. H01L 31/00; H01L 31/04; H01L 21/78

(52) U.S. Cl. 136/256; 438/68; 438/73; 257/E21.599

(57) ABSTRACT

A thin-film solar cell (1) includes a transparent insulation substrate (2), a transparent electrode layer (3), a semiconductor photoelectric conversion layer (4) and a back electrode layer (5) sequentially formed on the transparent insulation substrate (2), and a separation trench (8) separating at least the back electrode layer (5). The transparent electrode layer (3) protrudes in a longitudinal direction of the separation trench (8), extending beyond the semiconductor photoelectric conversion layer (4) and back electrode layer (5). A method of fabricating the thin-film solar cell (1) is provided.

### TECHNICAL FIELD

The present invention relates to a thin-film solar cell and a method of fabricating a thin-film solar cell. Particularly, the present invention relates to a thin-film solar cell that allows the fabrication cost to be reduced and the output improved, and a method of fabricating the thin-film solar cell.

### BACKGROUND ART

With regards to solar cells converting the energy of sunlight directly into electric energy, various types are now put into practical use. Particularly, development of a thin-film solar cell employing a thin film of amorphous silicon or microcrystalline silicon is now in progress in view of allowing fabrication at low cost by virtue of the low-temperature process and area increase.

FIG. 40 is a schematic plan view of an example of a conventional thin-film solar cell. FIG. 41 is a schematic sectional view of the perimeter region of a thin-film solar cell 100 shown in FIG. 40. Although in practice an EVA sheet is provided on the surface of a back electrode layer 5 and thermal compression bonding is applied with a protection film on the EVA sheet, representation thereof is not provided in FIG. 41 for the sake of simplification.

Conventional thin-film solar cell 100 shown in FIGS. 40 and 41 has a structure in which a transparent electrode layer 3, a semiconductor photoelectric conversion layer 4 formed of an amorphous silicon thin film, and a back electrode layer 5 are stacked in the cited order on a transparent insulation substrate 2. Transparent electrode layer 3 is separated by a first separation trench 6 filled with semiconductor photoelectric conversion layer 4. Semiconductor photoelectric conversion layer 4 and back electrode layer 5 are separated by a second separation trench 8. Then, through a contact line 7 corresponding to removal of semiconductor photoelectric conversion layer 4 by patterning using a laser beam or the like, adjacent cells are electrically connected in series to constitute a cell-integrated region 11.

At the neighborhood of the end in a direction orthogonal to the longitudinal direction of second separation trench 8, a current drawout electrode 10 is formed on the surface of transparent electrode layer 3, as shown in FIG. 41. Further, a perimeter trench 12 is formed to surround cell-integrated region 11, as shown in FIG. 40. A laminate 13 including transparent electrode layer 3, semiconductor photoelectric conversion layer 4 and back electrode layer 5 is formed at the outer side region of perimeter trench 12.

A method of fabricating this conventional thin-film solar cell 100 will be described hereinafter. First, transparent electrode layer 3 is stacked on transparent insulation substrate 2. Then, transparent electrode layer 3 is partially removed by laser scribing to form first separation trench 6. Moreover, the entire perimeter of transparent electrode layer 3 is removed by laser scribing to form perimeter trench 12.

Next, semiconductor photoelectric conversion layer 4 is deposited through plasma CVD by sequentially stacking a p layer, i layer, and n layer formed of amorphous silicon thin film so as to cover transparent electrode layer 3 separated by first separation trench 6. Then, semiconductor photoelectric conversion layer 4 is partially removed by laser scribing to form contact line 7.

Then, back electrode layer 5 is stacked so as to cover semiconductor photoelectric conversion layer 4. Accordingly, contact line 7 is filled with back electrode layer 5.

Next, laser scribing is employed to form second separation trench 8 separating semiconductor photoelectric conversion layer 4 and back electrode layer 5. Further, the surface of transparent insulation substrate 2 is exposed at perimeter trench 12 by removing a region of semiconductor photoelectric conversion layer 4 and back electrode layer 5 corresponding to perimeter trench 12.

The region of transparent electrode layer 3, semiconductor photoelectric conversion layer 4, and back electrode layer 5 located at an outer side than perimeter trench 12 is removed by polishing along the entire perimeter, followed by rinsing the polished portion. Thus, laminate 13 is provided at the outer side of perimeter trench 12. Then, current drawout electrode 10 is formed on the surface of transparent electrode layer 3 exposed at the neighborhood of either end in the direction orthogonal to the longitudinal direction of second separation trench 8.

Finally, an EVA sheet is provided on the surface of back electrode layer 5. Then, thermal compression bonding is applied with a protection film provided on the EVA sheet. Thus, conventional thin-film solar cell 100 of FIG. 40 is produced.

Patent Document 1: Japanese Patent Laying-Open No. 2000-150944

### DISCLOSURE OF THE INVENTION

### Problems to be Solved by the Invention

A metal frame will be attached to the perimeter region of thin-film solar cell 100 set forth above. From the standpoint of safety, an insulation portion must be provided between cell-integrated region 11 and the metal frame. IEC61730 that is one standard in association with insulation defines that an insulation portion greater than or equal to 8.4 mm, when the system voltage is 1000 V, for example, must be provided between cell-integrated region 11 and the metal frame.

Thus, at a predetermined region in the perimeter portion of thin-film solar cell 100 set forth above, transparent electrode layer 3, semiconductor photoelectric conversion layer 4, and back electrode layer 5 are removed to expose the surface of transparent insulation substrate 2, corresponding to an insulation portion.

For the purpose of forming the above-described insulation portion in conventional thin-film solar cell 100 set forth above, the steps of polishing and rinsing are required. There was a problem that the fabrication cost of thin-film solar cell 100 is increased.

Further, laminate 13 must be provided without any scratch formed at the end face of semiconductor photoelectric conversion layer 4 in cell-integrated region 11 by the aforementioned polishing. Accordingly, the ratio of the formation region of cell-integrated region 11 to the surface of transparent insulation substrate 2 is reduced. Thus, the region for power generation is reduced, leading to the problem that the output is reduced.

Alternative to the method through polishing set forth above, the perimeter region of transparent electrode layer 3, semiconductor photoelectric conversion layer 4 and back electrode layer 5 is irradiated with a laser beam to have these layers removed at one time (laser scribing).

However, this method is disadvantageous in that a portion of transparent electrode layer 3 evaporated by the irradiation with the laser beam will adhere to semiconductor photoelectric conversion layer 4 to cause a leak path. Current will flow through the leak path, leading to the problem of the output of thin-film solar cell 100 being degraded.

In view of the foregoing, an object of the present invention is to provide a thin-film solar cell allowing the fabrication cost to be reduced and the output improved, and a method of fabricating the thin-film solar cell.

### Means for Solving the Problems

The present invention is directed to a thin-film solar cell including a transparent insulation substrate, as well as a transparent electrode layer, a semiconductor photoelectric conversion layer, and a back electrode layer sequentially stacked on the transparent insulation substrate. The thin-film solar cell also includes a separation trench separating at least the back electrode layer. The transparent electrode layer protrudes in the longitudinal direction of the separation trench, extending beyond the semiconductor photoelectric conversion layer and back electrode layer. In the present invention, another layer may be formed or not formed between the transparent insulation substrate and transparent electrode layer, between the transparent electrode layer and semiconductor photoelectric conversion layer, and between the semiconductor photoelectric conversion layer and back electrode layer.

In the thin-film solar cell of the present invention, the protruding length of the transparent electrode layer is preferably greater than or equal to 100 μm and less than or equal to 1000 μm.

In the thin-film solar cell of the present invention, the transparent electrode layer preferably protrudes in a direction orthogonal to the longitudinal direction of the separation trench, extending beyond the semiconductor photoelectric conversion layer and back electrode layer.

Furthermore, in the thin-film solar cell of the present invention, a current drawout electrode is preferably formed at the back electrode layer located at the end of the direction orthogonal to the longitudinal direction of the separation trench.

The present invention is also directed to a method of fabricating a thin-film solar cell set forth above. The fabrication method for a thin-film solar cell includes the steps of stacking a transparent electrode layer on a transparent insulation substrate, stacking a semiconductor photoelectric conversion layer on the transparent electrode layer, stacking a back electrode layer on the semiconductor photoelectric conversion layer, forming a separation trench separating at least the back electrode layer, directing a first laser beam in a direction orthogonal to a longitudinal direction of the separation trench to remove the semiconductor photoelectric conversion layer and back electrode layer located at a radiation region by the first laser beam, and directing a second laser beam to a region further outer than the radiation region by the first laser beam with respect to the longitudinal direction of the separation trench to remove the transparent electrode layer, semiconductor photoelectric conversion layer and back electrode layer located at a radiation region by the second laser beam.

In the method of fabricating a thin-film solar cell of the present invention, a YAG laser beam of a second harmonic generation or a YVO₄ laser beam of a second harmonic generation can be employed as the first laser beam.

In the method of fabricating a thin-film solar cell of the present invention, a YAG laser beam of a fundamental wave or a YVO₄ laser beam of a fundamental wave can be employed as the second laser beam.

### EFFECTS OF THE INVENTION

According to the present invention, there can be provided a thin-film solar cell allowing the fabrication cost to be reduced and the output improved, and a method of fabricating the thin-film solar cell.

### BRIEF DESCRIPTION OF THE DRAWINGS

FIG. 1 is a schematic plan view of an example of a thin-film solar cell of the present invention.

FIG. 2 is a schematic sectional view of the thin-film solar cell of FIG. 1, wherein (a) and (b) correspond to sectional views taken along IIA-IIA and IIB-IIB, respectively, of FIG. 1.

FIG. 3 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 4 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 5 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 6 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 7 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 8 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 9 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 10 is a schematic sectional view to illustrate a part of a method of fabricating the thin-film solar cell of the present invention shown in FIG. 1, wherein (a) and (b) correspond to sectional views taken along the direction of IIA-IIA (longitudinal direction of separation trench) and IIB-IIB (direction orthogonal to the longitudinal direction of separation trench), respectively, of FIG. 1.

FIG. 11 is a schematic plan view of another example of a thin-film solar cell of the present invention

FIG. 12 is a sectional view of the thin-film solar cell of FIG. 11, wherein (a) and (b) correspond to sectional views taken along XIIA-XIIA and XIIB-XIIB, respectively, of FIG. 11.

FIG. 13 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively of FIG. 11.

FIG. 14 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 15 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 16 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 17 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 18 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 19 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 20 is a schematic sectional view to illustrate a part of a method of fabricating the thin-film solar cell of the present invention shown in FIG. 11, wherein (a) and (b) correspond to sectional views taken along the direction of XIIA-XIIA (longitudinal direction of separation trench) and the direction of XIIB-XIIB (direction orthogonal to the longitudinal direction of separation trench), respectively, of FIG. 11.

FIG. 21 is a schematic plan view of a thin-film solar cell of Comparative Example 1.

FIG. 22 is a schematic sectional view of the thin-film solar cell of FIG. 21, wherein (a) and (b) correspond to sectional views taken along XXIIA-XXIIA and XXIIB-XXIIB, respectively, of FIG. 21.

FIG. 23 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 24 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 25 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 26 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 27 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 28 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively, of FIG. 21.

FIG. 29 is a schematic sectional view to illustrate a part of a method of fabricating the thin-film solar cell of Comparative Example 1 shown in FIG. 21, wherein (a) and (b) correspond to sectional views taken along the direction of XXIIA-XXIIA (longitudinal direction of separation trench) and the direction of XXIIB-XXIIB (direction orthogonal to the longitudinal direction of separation trench), respectively of FIG. 21.

FIG. 30 is a schematic plan view of a thin-film solar cell of Comparative Example 2.

FIG. 31 is a schematic sectional view of the thin-film solar cell of FIG. 30, wherein (a) and (b) are sectional views taken along XXXIA-XXXIA and XXXIB-XXXIB, respectively, of FIG. 30.

FIG. 32 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 33 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 34 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 35 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 36 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 37 is a schematic sectional view to illustrate a part of a method of fabricating the thin-film solar cell of Comparative Example 2 shown in FIG. 30, wherein (a) and (b) correspond to sectional views taken alone the direction of XXXIA-XXXIA (longitudinal direction of separation trench) and the direction of XXXIB-XXXIB (direction orthogonal to the longitudinal direction of separation trench), respectively, of FIG. 30.

FIG. 38 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 39 is a schematic sectional view to illustrate a part of a method of fabricating the thin-film solar cell of Comparative Example 2 shown in FIG. 30, wherein (a) and (b) correspond to sectional views taken along the direction of XXXIA-XXXIA (longitudinal direction of separation trench) and the direction of XXXIB-XXXIB (direction orthogonal to the longitudinal direction of separation trench), respectively, of FIG. 30.

FIG. 40 is a schematic plan view of an example of a conventional thin-film solar cell.

FIG. 41 is a schematic sectional view of the perimeter region of the conventional thin-film solar cell of FIG. 40.

### DESCRIPTION OF THE REFERENCE SIGNS

1, 100 thin-film solar cell; 2 transparent insulation substrate, 3 transparent electrode layer; 4 semiconductor photoelectric conversion layer; 5 back electrode layer; 6 first separation trench; 7 contact line; 8 second separation trench; 9, 12 perimeter trench; 10 electrode; 11 cell-integrated region; 13 laminate.

### BEST MODES FOR CARRYING OUT THE INVENTION

Embodiments of the present invention will be described hereinafter. In the drawings of the present invention, the same reference characters denote the same or corresponding elements.

### First Embodiment

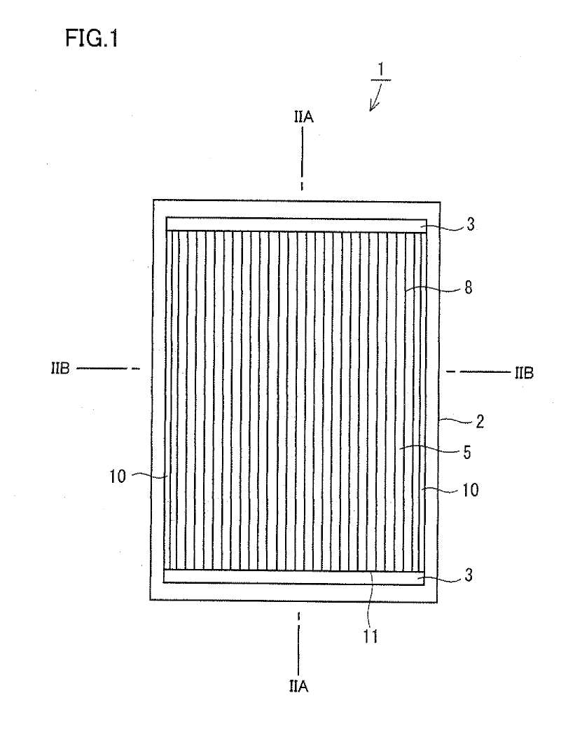

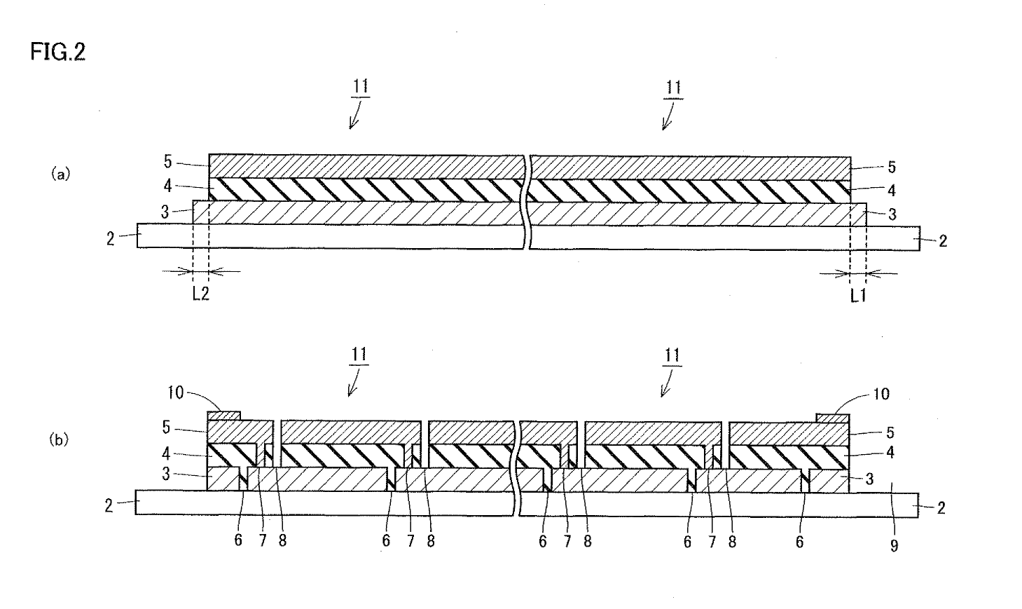

FIG. 1 is a schematic plan view of an example of a thin-film solar cell of the present invention. FIG. 2(a) represents a schematic sectional view taken along IIA-IIA of FIG. 1, and FIG. 2(b) represents a schematic sectional view taken along IIB-IIB of FIG. 1. A thin-film solar cell 1 of the present invention shown in FIG. 1 has a transparent electrode layer 3, a semiconductor photoelectric conversion layer 4, and a back electrode layer 5 stacked in the cited order on a transparent insulation substrate 2, as shown in FIGS. 2(a) and 2(b).

Referring to FIG. 2(b), transparent electrode layer 3 is separated by first separation trenches 6 filled with semiconductor photoelectric conversion layer 4. Semiconductor photoelectric conversion layer 4 and back electrode layer 5 are separated by second separation trenches 8. Adjacent cells are electrically connected in series through a contact line 7 corresponding to the region where semiconductor photoelectric conversion layer 4 is removed by laser scribing to constitute a cell-integrated region 11.

Referring to FIG. 2(b), a current drawout electrode 10 is formed on the surface of back electrode layer 5 at either end in the direction orthogonal to the longitudinal direction of second separation trench 8 shown in FIG. 1. Each electrode 10 is formed parallel to the longitudinal direction of second separation trench 8, as shown in FIG. 1.

Referring to FIG. 2(a), transparent electrode layer 3 protrudes in the longitudinal direction of second separation trench 8, extending beyond semiconductor photoelectric conversion layer 4 and back electrode layer 5.

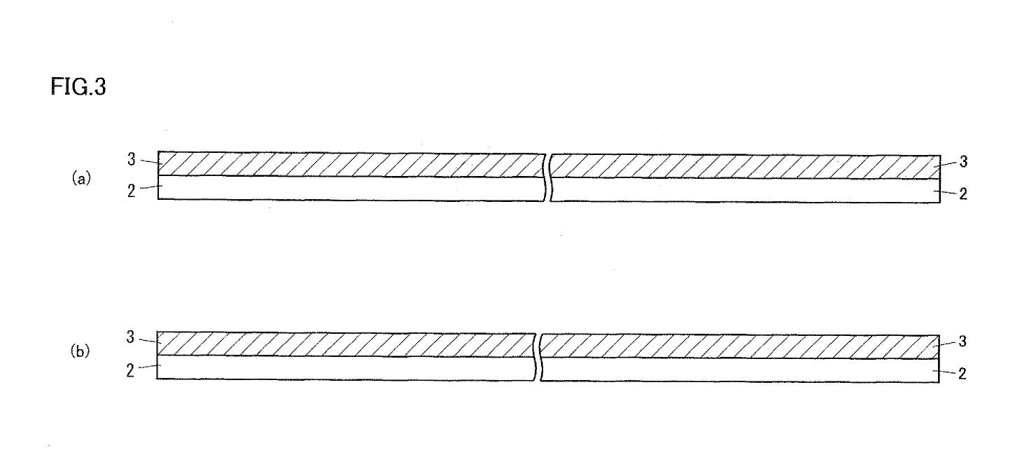

A method of fabricating thin-film solar cell 1 of the present invention shown in FIG. 1 will be described hereinafter with reference to schematic sectional views of FIGS. 3-10. In FIGS. 3-10, (a) corresponds to a cross section taken along the direction of IIA-IIA (longitudinal direction of separation trench), and (b) corresponds to a cross section taken along direction of IIB-IIB (direction orthogonal to the longitudinal direction of separation trench) of FIG. 1.

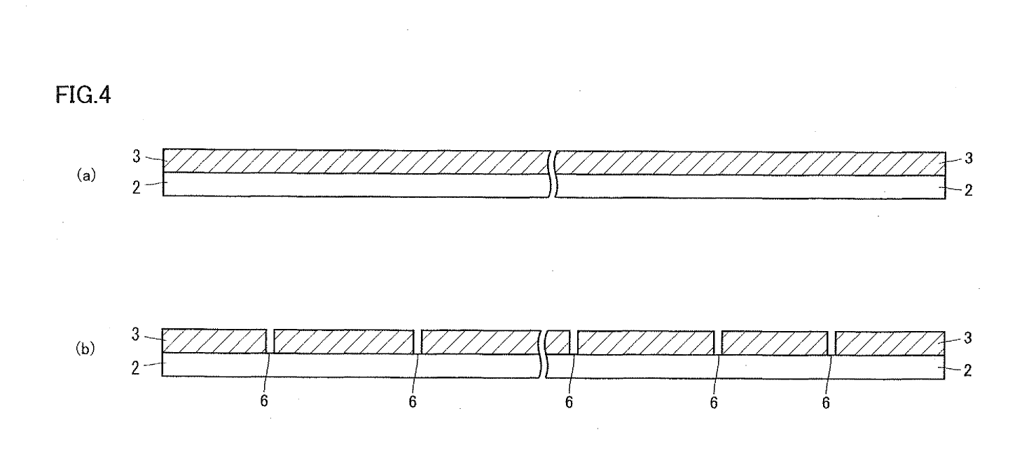

First, referring to FIGS. 3(a) and 3(b), transparent electrode layer 3 is deposited on transparent insulation substrate 2. Then, a laser beam is directed in the longitudinal direction of the separation trench from the side of transparent insulation substrate 2 for laser beam radiation, whereby transparent electrode layer 3 is removed in stripes to form first separation trenches 6 separating transparent electrode layer 3. Since a laser beam is not directed in the direction orthogonal to the longitudinal direction of the separation trench, first separation trench 6 will not be formed in the direction orthogonal to the longitudinal direction of the separation trench, as shown in FIG. 4(a).

In the case where the inspection process includes an inspection step of the isolation resistance as the means for confirming whether first separation trench 6 has been obtained or not, a trench can be formed, one at each of the right and left sides of the direction orthogonal to the longitudinal direction of the separation trench. Further, in the case where a laser-worked trace is to be employed for an alignment mark in the subsequent steps, a trench can be formed, one at each of the right and left sides of the direction orthogonal to the longitudinal direction of the separation trench. Thus, when a trench is to be formed) one at each of the right and left sides of the direction orthogonal to the longitudinal direction of the separation trench, the trench formation region is preferably located at the region that will be eventually removed.

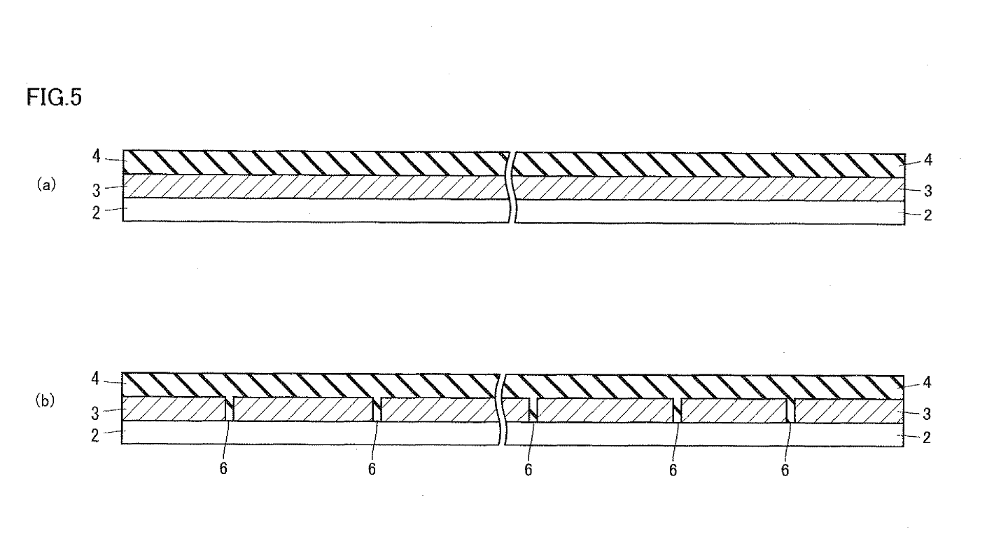

Then, a laminate is stacked by, for example, plasma CVD so as to cover transparent electrode layer 3 separated by first separation trenches 6. The laminate includes a p layer, an i layer, and an n layer formed of amorphous silicon thin film, and a p layer, an i layer, and an n layer formed of microcrystalline silicon thin film. Thus, semiconductor photoelectric conversion layer 4 is deposited, as shown in FIGS. 5(a) and 5(b).

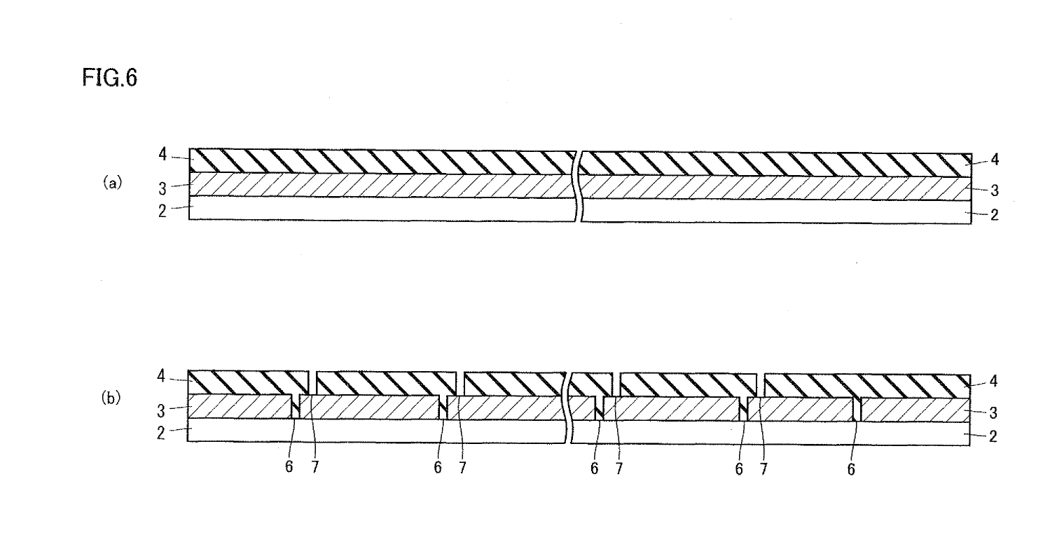

Then, a laser beam is directed in the longitudinal direction of the separation trench from the side of transparent insulation substrate 2 for laser beam radiation. Accordingly, semiconductor photoelectric conversion layer 4 is partially removed in stripes to form contact lines 7 shown in FIG. 6(b). Since a laser beam is not directed in the direction orthogonal to the longitudinal direction of the separation trench, a contact line 7 will not be formed in the direction orthogonal to the longitudinal direction of the separation trench, as shown in FIG. 6(a).

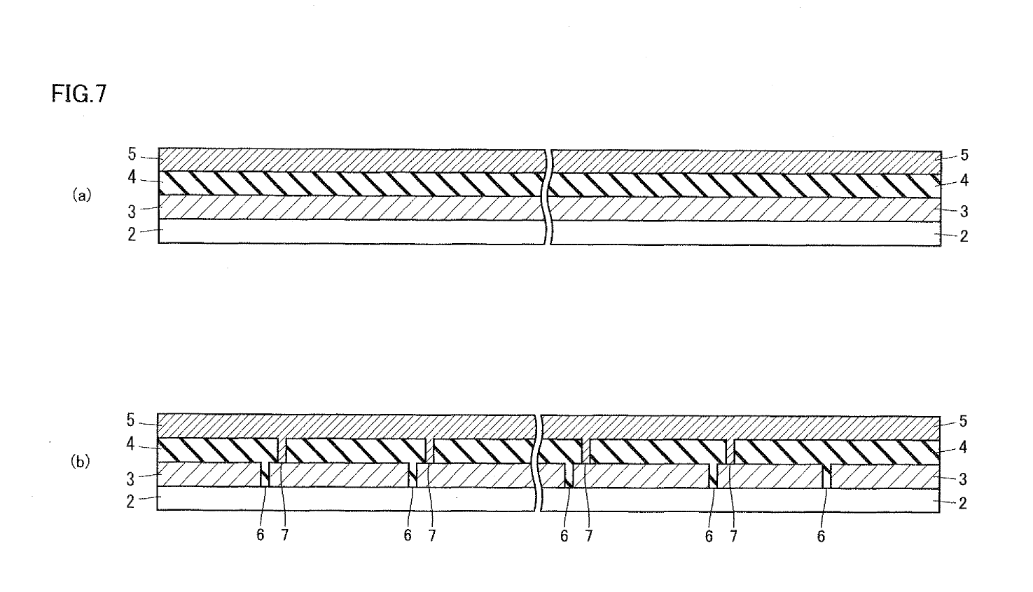

Then, as shown in FIGS. 7(a) and 7(b), back electrode layer 5 is stacked so as to cover semiconductor photoelectric conversion layer 4. Accordingly, contact line 7 is filled with back electrode layer 5, as shown in FIG. 7(b).

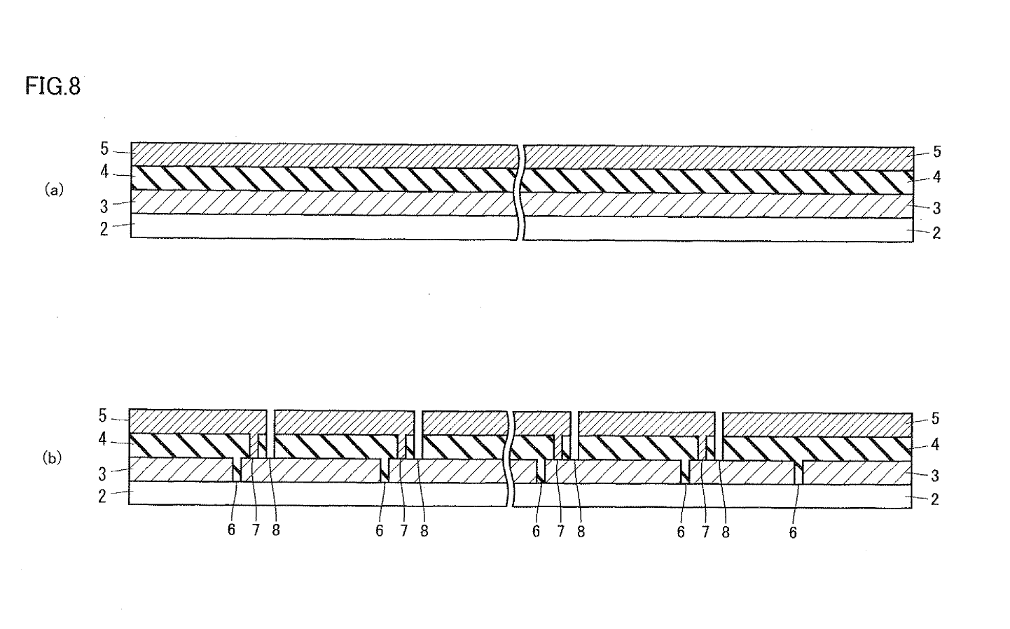

Next, a laser beam is directed in the longitudinal direction of the separation trench from the side of transparent insulation substrate 2 for laser beam radiation to remove semiconductor photoelectric conversion layer 4 and back electrode layer 5 in stripes. Thus, second separation trenches 8 shown in FIG. 8(b) are formed. Since a laser beam is not directed in the direction orthogonal to the longitudinal direction of the separation trench, second separation trench 8 will not be formed in the direction orthogonal to the longitudinal direction of the separation trench, as shown in FIG. 8(a).

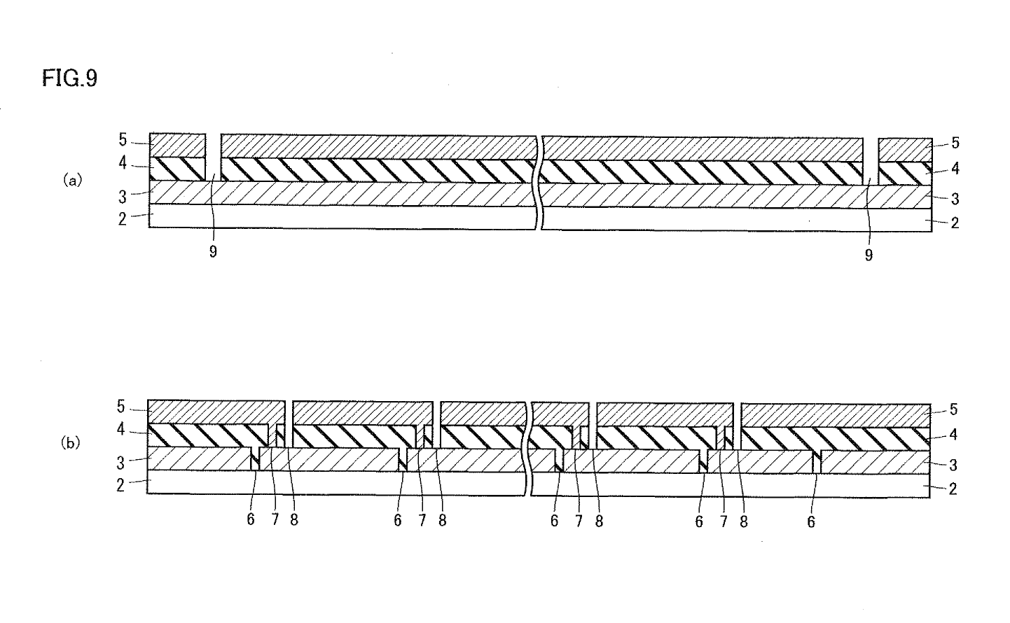

Subsequently, a laser beam (first laser beam) is directed in a direction orthogonal to the longitudinal direction of the separation trench from the side of transparent insulation substrate 2 for first laser beam radiation to remove semiconductor photoelectric conversion layer 4 and back electrode layer 5 in strips located at the neighborhood of respective ends in the longitudinal direction of the separation trench. Thus, a perimeter trench 9 is formed at the first laser beam radiation region, as shown in FIG. 9(a). Since the first laser beam is not directed in the longitudinal direction of the separation trench, perimeter trench 9 will not be formed in the longitudinal direction of the separation trench, as shown in FIG. 9(b).

The step of forming second separation trench 8 of FIG. 8 and the step of forming perimeter trench 9 of FIG. 9 are preferably carried out in the same laser step. This is because a laser beam of the same wavelength can be employed for the formation of second separation trench 8 and perimeter trench 9.

For the first laser beam, a YAG laser beam of a second harmonic generation (wavelength: 532 nm), or a YVO₄ (Yttrium Orthovanadate) laser beam of a second harmonic generation (wavelength: 532 nm), for example, may be employed. The YAG laser beam of the second harmonic generation and the YVO₄ laser beam of the second harmonic generation are apt to pass through transparent insulation substrate 2 and transparent electrode layer 3 to be absorbed by semiconductor photoelectric conversion layer 4. In the case where the YAG or YVO₄ laser beam of the second harmonic generation is employed for the first laser beam, selective heating of semiconductor photoelectric conversion layer 4 allows evaporation of semiconductor photoelectric conversion layer 4 at the region of the heat and back electrode layer 5 in contact with the heated region of semiconductor photoelectric conversion layer 4. The intensity of the YAG laser beam and YVO₄ laser beam having the second harmonic generation is preferably selected at a level that does not damage transparent electrode layer 3.

In the present invention, the YAG laser refers to an Nd:YAG laser, based on yttrium aluminium garnet (Y₃Al₅O₁₂) crystal containing neodymium ion (Nd³⁺). From the YAG laser, a YAG laser beam of the fundamental wave (wavelength: 1064 nm) is oscillated. By converting the wavelength to ½, a YAG laser beam of the second harmonic generation (wavelength: 532 nm) can be obtained.

In the present invention, the YVO₄ laser refers to an Nd: YVO₄ laser, based on YVO₄ crystal containing neodymium ion (Nd³⁺). From the YVO₄ laser, a YVO₄ laser beam of the fundamental wave (wavelength: 1064 nm) is oscillated. By converting the wavelength to ½, a YVO₄ laser beam of the second harmonic generation (wavelength: 532 nm) can be obtained.

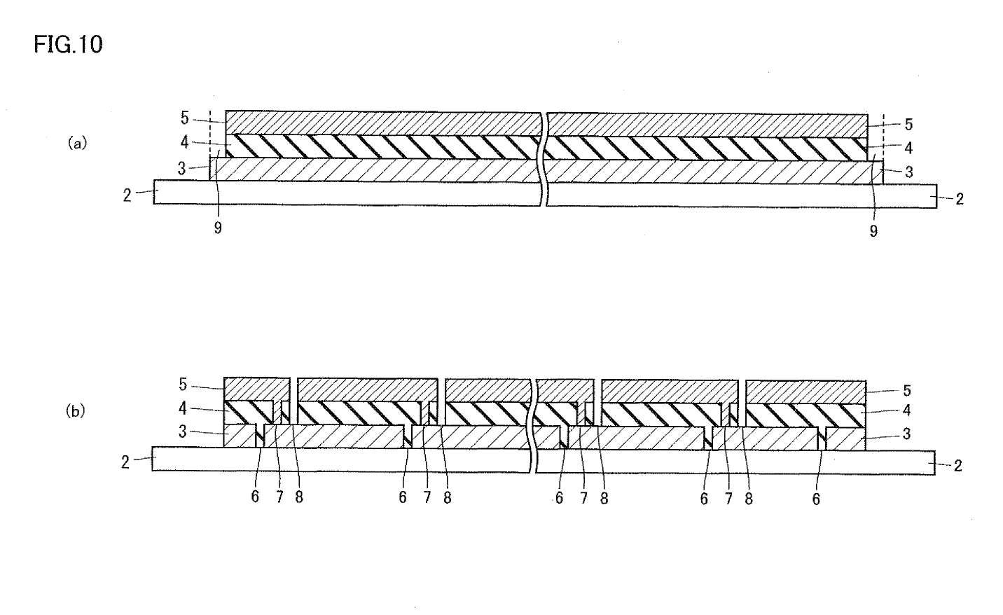

Then, towards the region located further outer than perimeter trench 9, a laser beam (second laser beam) having a wavelength differing from that of the first laser beam is directed from the side of transparent insulation substrate 2 in the direction orthogonal to the longitudinal direction of the separation trench for second laser beam radiation. As shown in FIG. 10(a), transparent electrode layer 3, semiconductor photoelectric conversion layer 4 and back electrode layer 5 located at the outer side region of perimeter trench 9 are removed.

In addition, referring to FIG. 10(b), by directing a second laser beam in the longitudinal direction of the separation trench from the side of transparent insulation substrate 2 for second laser beam radiation, transparent electrode layer 3, semiconductor photoelectric conversion layer 4 and back electrode layer 5 located at respective ends in the direction orthogonal to the longitudinal direction of the separation trench are removed in strips.

For the second laser beam, a YAG laser beam of the fundamental wave (wavelength: 1064 nm) or a YVO₄ laser beam of the fundamental wave is preferably employed. The YAG laser beam of the fundamental wave and the YVO₄ laser beam of the fundamental wave are apt to pass through transparent insulation substrate 2 to be absorbed by transparent electrode layer 3. In the case where the YAG laser beam of the fundamental wave or the YVO₄ laser beam of the fundamental wave is employed as the second laser beam, selective heating of transparent electrode layer 3 allows evaporation of transparent electrode layer 3, semiconductor photoelectric conversion layer 4 and back electrode layer 5 by the heat thereof.

The width of the second laser beam (the maximum value of the width of the second laser beam in the direction perpendicular to the scanning direction of the second laser beam) is preferably greater than or equal to 250 μm, and more preferably greater than or equal to 500 μm, in view of efficiently removing transparent electrode layer 3, semiconductor photoelectric conversion layer 4, and back electrode layer 5. The cross sectional shape of the second laser beam (the shape of the cross section perpendicular to the direction of directing the second laser beam) is preferably, but not particularly limited to, a square or rectangle, as compared to a circle or ellipses.

Then, as shown in FIG. 2(b), a current drawout electrode 10 extending in the longitudinal direction of the separation trench is formed on the surface of back electrode layer 5 at respective ends in the direction orthogonal to the longitudinal direction of the separation trench.

Finally, an EVA sheet, for example, is provided on the surface of back electrode layer 5 subsequent to formation of electrode 10. A protection film formed of a 3-layer stack film of PET (Polyester)/Al (Aluminium)/PET is provided on the EVA sheet. By thermal compression bonding thereon, thin-film solar cell 1 of the configuration shown in FIG. 1 is completed.

Thin-film solar cell 1 of the configuration shown in FIG. 1, produced as set forth above includes, as shown in FIGS. 2(a) and 2(b), transparent electrode layer 3, semiconductor photoelectric conversion layer 4, and back electrode layer 5 sequentially stacked on transparent insulation substrate 2, wherein transparent electrode layer 3 extends beyond semiconductor photoelectric conversion layer 4 and back electrode layer 5 in the longitudinal direction of the separation trench.

The present embodiment is dispensed with the two steps of polishing and rinsing to form an insulation region between the perimeter region of thin-film solar cell 1 and cell-integrated region 11, allowing reduction in the number of processing steps. Therefore, the fabrication cost of the thin-film solar cell can be reduced as compared to a conventional one.

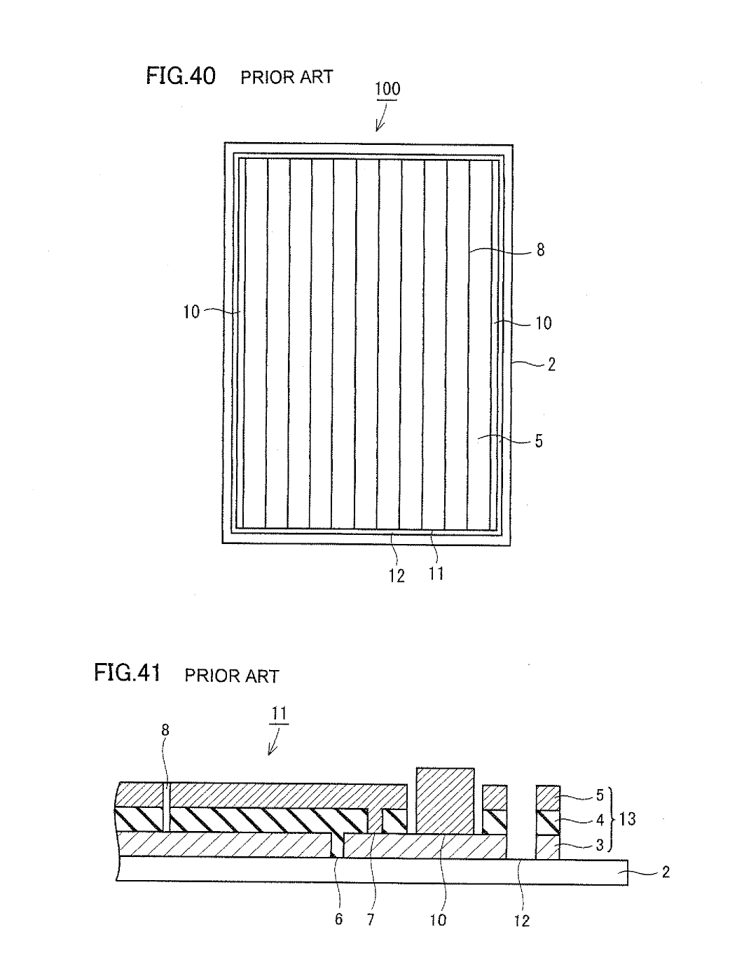

Since a polishing step is not required to form the perimeter insulation region of thin-film solar cell 1 in the present embodiment, a laminate 13 for scratch protection does not have to be left at the perimeter region of cell-integrated region 11, as in conventional thin-film solar cell 100 shown in FIGS. 40 and 41. Therefore, the ratio of the formation region for cell-integrated region 11 with respect to the surface of transparent insulation substrate 2 can be increased as compared to a conventional one, so that degradation in the power generation region can be suppressed. As a result, the output can be improved.

Further in the present embodiment, only semiconductor photoelectric conversion layer 4 and back electrode layer 5 can be removed without removal of transparent electrode layer 3, in the first laser beam radiation region. Accordingly, the vertical cross section of semiconductor photoelectric conversion layer 4 and back electrode layer 5 is exposed at perimeter trench 9, as shown in FIG. 10(a). Even in the case where a region of transparent electrode layer 3 located outer than the first laser beam radiation region is evaporated by the step of directing the second laser beam, there will be present a distance between the exposed vertical cross section of semiconductor photoelectric conversion layer 4 and evaporated back electrode layer 5, at least corresponding to the region irradiated with the first laser beam (perimeter trench 9). Accordingly, reattachment of evaporated transparent electrode layer 3 to the vertical cross section of semiconductor photoelectric conversion layer 4 is less likely in the present embodiment in view of the first laser beam radiation region (perimeter trench 9), as compared to the conventional case where the portions of transparent electrode layer 3, semiconductor photoelectric conversion layer 4 and back electrode layer 5 at the perimeter region are evaporated at one time. Thus, leakage current at the perimeter region of the thin-film solar cell can be reduced.

In the present embodiment, the protruding lengths L1 and L2 shown in FIG. 2(a) of transparent electrode layer 3 in the longitudinal direction of the separation trench are preferably greater than or equal to 100 μm and less than or equal to 1000 μm. If the protruding lengths L1 and L2 of transparent electrode layer 3 are less than 100 μm, accuracy in mechanical machining will be required when processing is carried out with the second laser beam, leading to increase in the fabrication cost. Moreover, reattachment of transparent electrode layer 3 evaporated by the second laser beam to the exposed vertical cross section of semiconductor photoelectric conversion layer 4 is more likely. If protruding lengths L1 and L2 of transparent electrode layer 3 exceed 1000 μm, the power generation region will be reduced, leading to degradation in the output. As used herein, L1 and L2 may be identical or different in length.

For transparent insulation substrate 2, a glass substrate, for example, or the like may be employed. For transparent electrode layer 3, a layer formed of SnO₂ (tin oxide), ITO (Indium Tin Oxide), ZnO (zinc oxide) or the like may be employed. Transparent electrode layer 3 can be formed by, but not particularly limited to, the well-known sputtering method, evaporation method, ion plating, or the like.

For semiconductor photoelectric conversion layer 4, various structures may be employed such as a structure in which a p layer, i layer, and n layer formed of an amorphous silicon thin film are sequentially stacked; a tandem configuration based on a combination of a structure in which a p layer, i layer, and n layer formed of an amorphous silicon thin film are sequentially stacked and a structure in which a p layer, i layer, and n layer formed of a microcrystalline silicon thin film are sequentially stacked; a structure in which an intermediate layer such as of ZnO is inserted between a structure in which a p layer, i layer, and n layer formed of an amorphous silicon thin film are sequentially stacked and a structure in which a p layer, i layer, and n layer formed of a microcrystalline silicon thin film are sequentially stacked; or the like. Alternatively, a mixture of layers formed of an amorphous silicon thin film and of a microcrystalline silicon thin film for the p layer, the i layer, and the n layer may be employed such as using an amorphous silicon thin film for at least one of the p layer, i layer, and n layer and using a microcrystalline silicon thin film for the remaining p layer, i layer, and n layer. For example, a structure may be employed in which a p layer and i layer formed of an amorphous silicon thin film and an n layer formed of a microcrystalline silicon thin film are combined.

For the aforementioned amorphous silicon thin film, a thin film formed of hydrogenated amorphous silicon type semiconductor (a-Si:H) having the silicon dangling bond terminated by hydrogen may be employed. For the aforementioned microcrystalline silicon thin film, hydrogenated microcrystalline silicon type semiconductor (μc-Si:H) having the silicon dangling bond terminated with hydrogen may be employed.

The thickness of semiconductor photoelectric conversion layer 4 can be set to, for example, greater than or equal to 200 nm and less than or equal to 5 μm.

Although the above embodiment has been described based on the case where plasma CVD is employed for forming semiconductor photoelectric conversion layer 4, the method for forming semiconductor photoelectric conversion layer 4 in the present invention is not particularly limited thereto.

The structure of back electrode layer 5 is also not particularly limited. By way of example, a laminate of a metal thin film formed of silver or aluminium and a transparent conductive film such as of ZnO may be employed. The thickness of the metal thin film can be set to, for example, greater than or equal to 100 nm and less than or equal to 1 μm. The thickness of the transparent conductive film can be set to greater than or equal to 20 nm and less than or equal to 200 nm.

Further, a single or a plurality of metal thin films may be employed for back electrode layer 5. Providing a transparent conductive film between back electrode layer 5 formed of a metal thin film including one or a plurality of layers and semiconductor photoelectric conversion layer 4 is advantageous in that the diffusion of metal atoms from back electrode layer 5 formed of a metal thin film towards semiconductor photoelectric conversion layer 4 can be prevented, allowing improvement in the reflectance of the sunlight by back electrode layer 5. The formation method of back electrode layer 5 includes, but not particularly limited to, sputtering.

### Second Embodiment

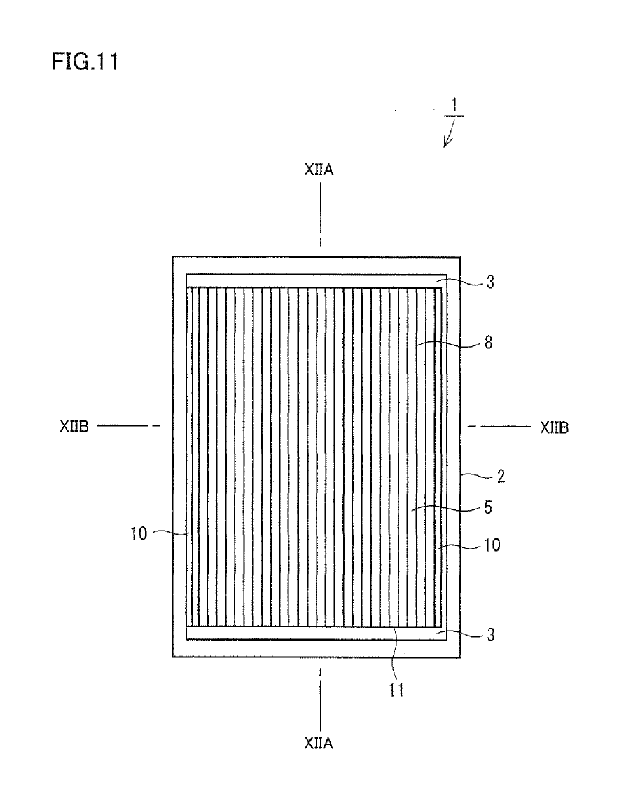

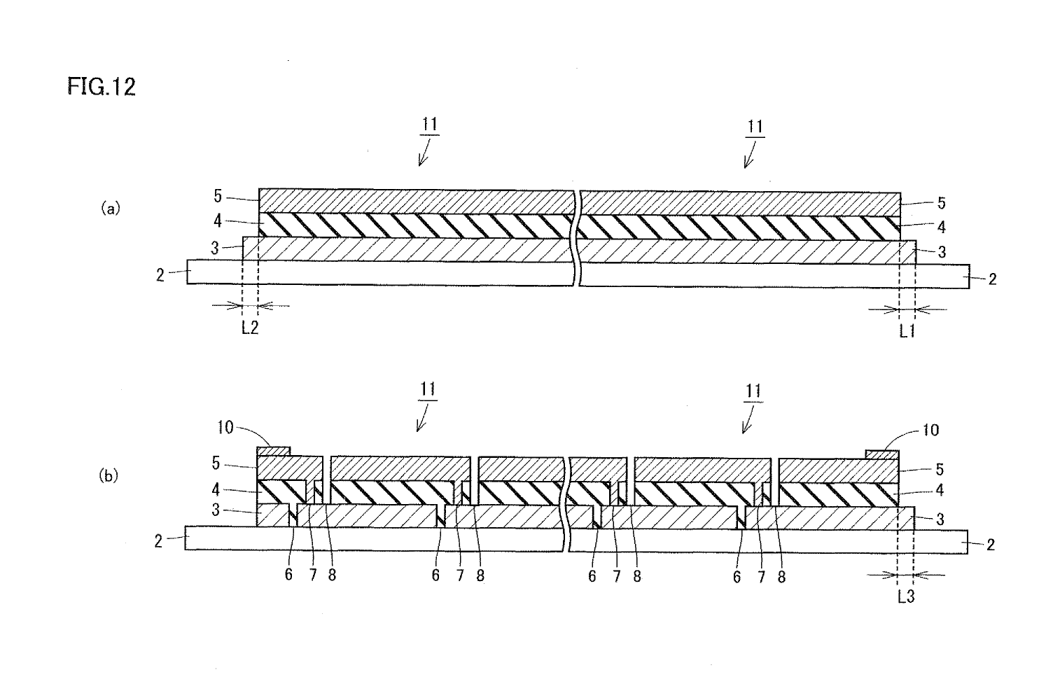

FIG. 11 is a schematic plan view of another example of a thin-film solar cell of the present invention. FIG. 12(a) represents a schematic sectional view taken along XIIA-XIIA of FIG. 11, and FIG. 12(b) represents a schematic sectional view taken along XIIB-XIIB of FIG. 1.

Thin-film solar cell 1 shown in FIG. 11 is characterized in that transparent electrode layer 3 protrudes, not only in the longitudinal direction of the separation trench, extending beyond semiconductor photoelectric conversion layer 4 and back electrode layer 5, but also in one direction orthogonal to the longitudinal direction of the separation trench.

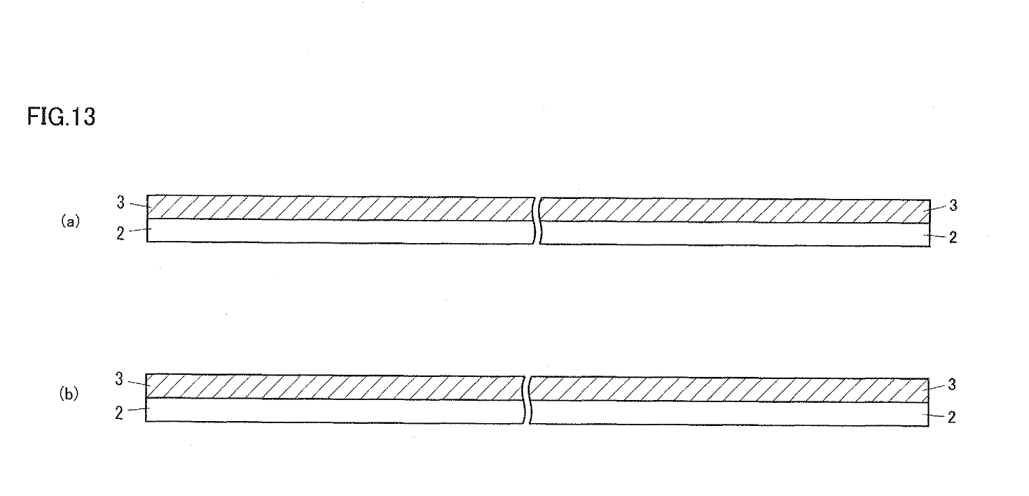

A method of fabricating thin-film solar cell 1 of the present invention shown in FIG. 1I will be described hereinafter with reference to schematic sectional views of FIGS. 13-20. In FIGS. 13-20, (a) corresponds to a cross section taken along the direction of XIIA-XIIA (longitudinal direction of separation trench) of FIG. 11, and (b) corresponds to a cross section taken along the direction of XIIB-XIIB (direction orthogonal to the longitudinal direction of separation trench) shown in FIG. 11.

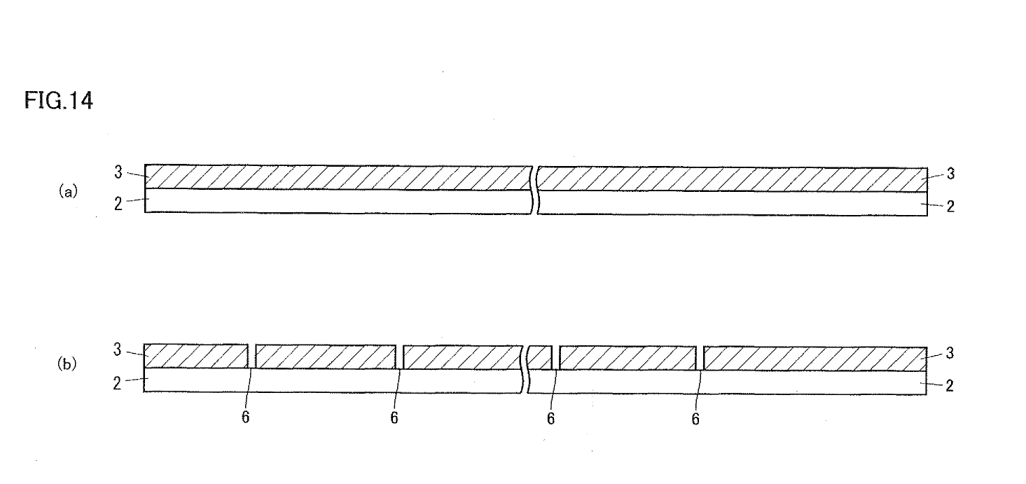

Referring to FIGS. 13(a) and 13(b), transparent electrode layer 3 is stacked on transparent insulation substrate 2. A laser beam is directed from the side of transparent insulation substrate 2 in a longitudinal direction of the separation trench for laser beam radiation to remove transparent electrode layer 3 in stripes, forming first separation trenches 6, as shown in FIG. 14(b). Since a laser beam is not directed in the direction orthogonal to the longitudinal direction of the separation trench, first separation trench 6 will not be formed in the direction orthogonal to the longitudinal direction of the separation trench, as shown in FIG. 14(a).

In the case where the inspection process includes an inspection step of the isolation resistance as the means for confirming whether first separation trench 6 has been obtained or not, a trench can be formed, one at each of the right and left sides of the direction orthogonal to the longitudinal direction of the separation trench. Further, in the case where a laser-worked trace is to be employed for an alignment mark in the subsequent steps, a trench can be formed, one at each of the right and left sides of the direction orthogonal to the longitudinal direction of the separation trench. Thus, when a trench is to be formed, one at each of the right and left sides of the direction orthogonal to the longitudinal direction of the separation trench, the trench formation region is preferably located at the region that will be eventually removed.

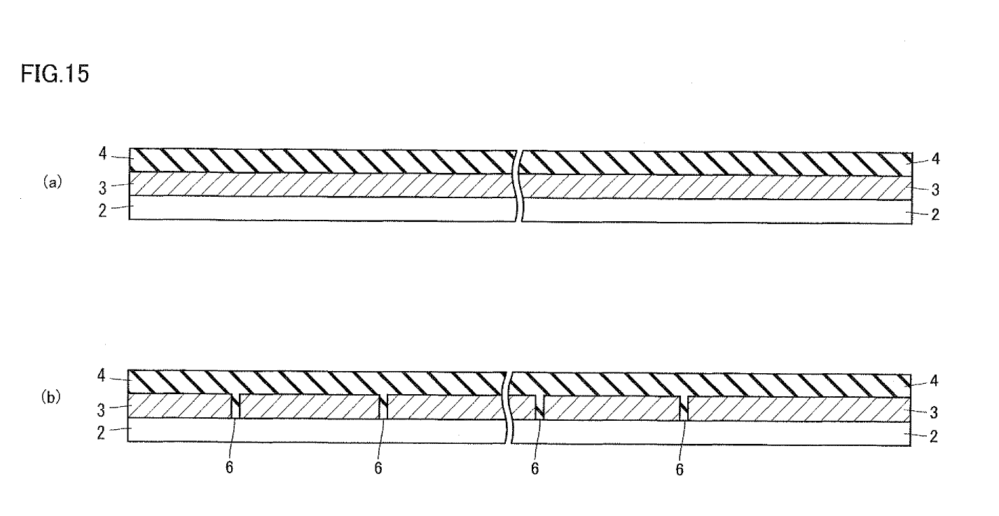

Then, a laminate including a p layer, i layer, and n layer formed of amorphous silicon thin film and a p layer, i layer, and n layer formed of microcrystalline silicon thin film is stacked so as to cover transparent electrode layer 3 separated by first separation trenches 6. Thus, semiconductor photoelectric conversion layer 4 is deposited, as shown in FIGS. 15(a) and 15(b).

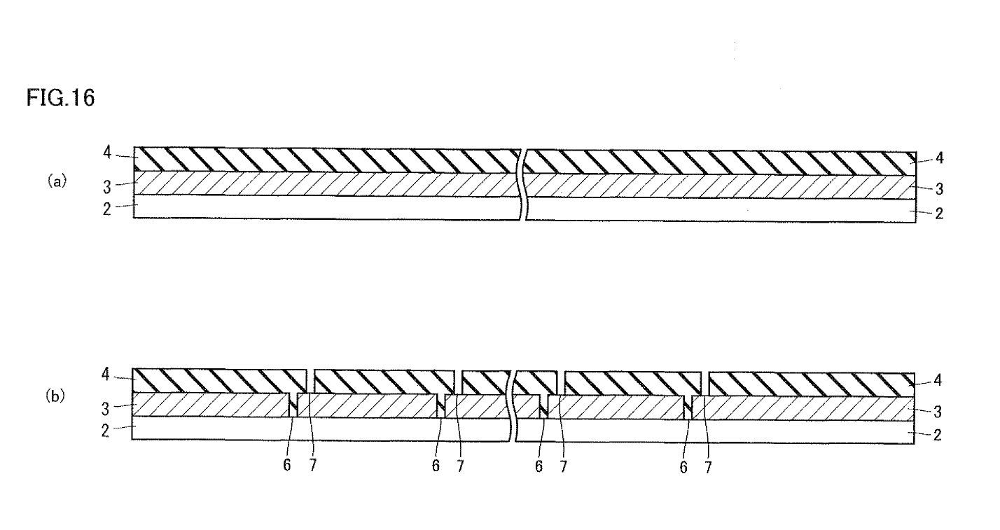

Then, a laser beam is directed in the longitudinal direction of the separation trench from the side of transparent insulation substrate 2 for laser beam radiation to remove semiconductor photoelectric conversion layer 4 partially in stripes. Thus, contact lines 7 shown in FIG. 16(b) are formed. Since a laser beam is not directed in a direction orthogonal to the longitudinal direction of the separation trench, contact line 7 will not be formed in the direction orthogonal to the longitudinal direction of the separation trench, as shown in FIG. 16(a).

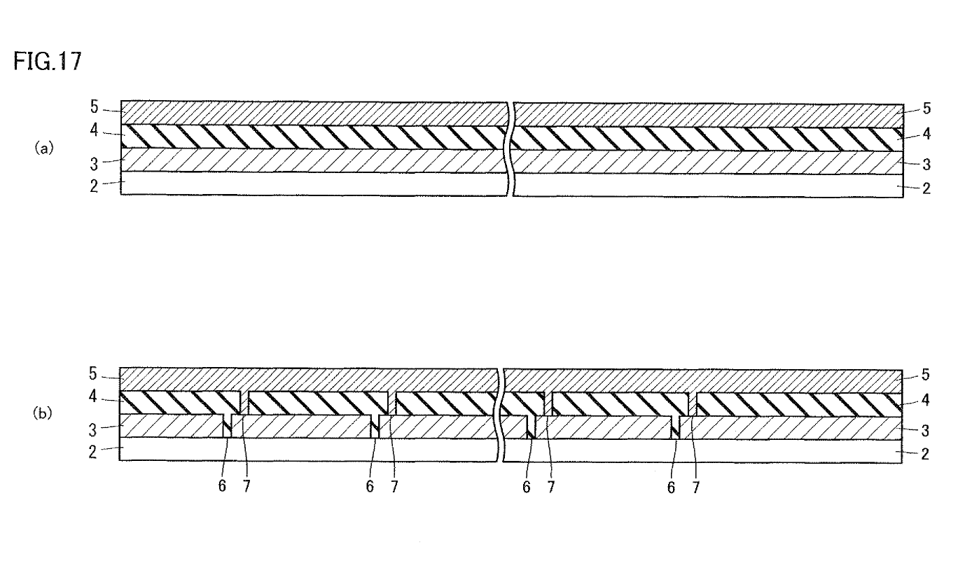

Referring to FIGS. 17(a) and 17(b), back electrode layer 5 is stacked so as to cover semiconductor photoelectric conversion layer 4. Accordingly, contact line 7 is filled with back electrode layer 5, as shown in FIG. 17(b).

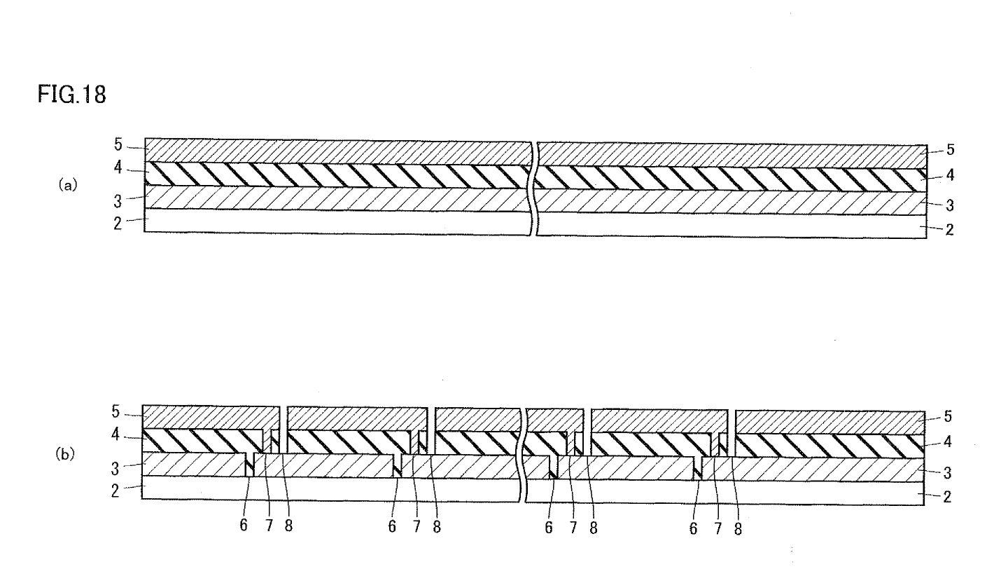

Then, a laser beam is directed in the longitudinal direction of the separation trench from the side of transparent insulation substrate 2 for laser beam radiation to remove semiconductor photoelectric conversion layer 4 and back electrode layer 5 in stripes. Thus, second separation trenches 8 shown in FIG. 18(b) are formed. Since a laser beam is not directed in the direction orthogonal to the longitudinal direction of the separation trench, second separation trench 8 will not be formed in the direction orthogonal to the longitudinal direction of the separation trench, as shown in FIG. 18(a).

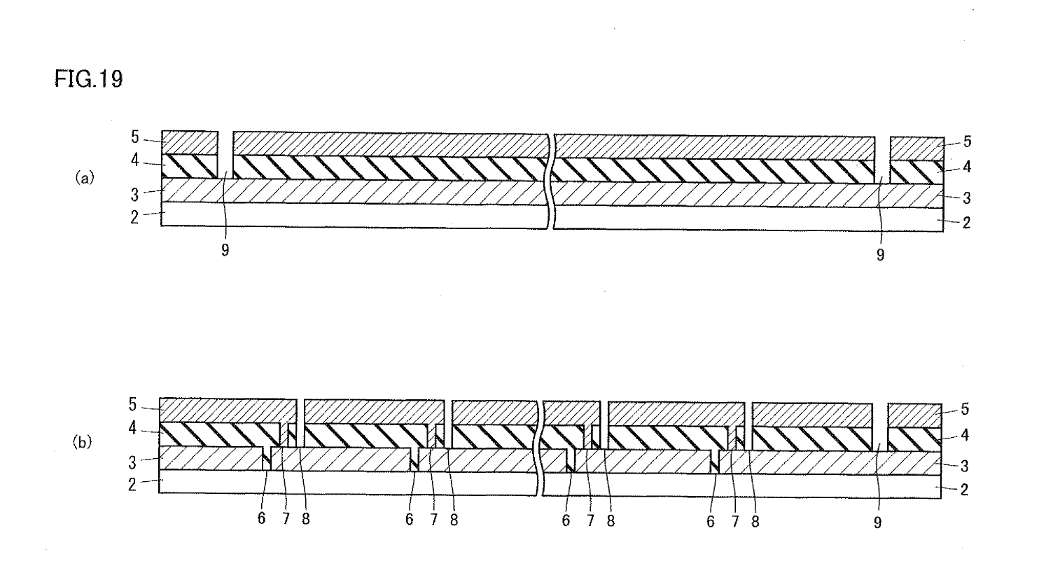

Then, a laser beam (first laser beam) is directed in a direction orthogonal to the longitudinal direction of the separation trench from the side of transparent insulation substrate 2 for first laser beam radiation to remove the region of semiconductor photoelectric conversion layer 4 and back electrode layer 5 in strips, located at the neighborhood of each side end in the longitudinal direction of the separation trench. Thus, perimeter trench 9 is formed at the first laser beam radiation region, as shown in FIG. 19(a).

Further, the first laser beam is directed in the longitudinal direction of the separation trench from the side of transparent insulation substrate 2 for first laser beam radiation to remove the portion of semiconductor photoelectric conversion layer 4 and back electrode layer 5 in strips, located at the neighborhood of one of the ends in the direction orthogonal to the longitudinal direction of the separation trench. Thus, perimeter trench 9 is formed at the first laser beam radiation region, as shown in FIG. 19(b).

The formation step of second separation trench 8 shown in FIG. 18 and the formation step of perimeter trench 9 shown in FIG. 19 are preferably carried out in the same laser step. This is because formation of second separation trench 8 and perimeter trench 9 can be carried out by a laser beam of the same wavelength.

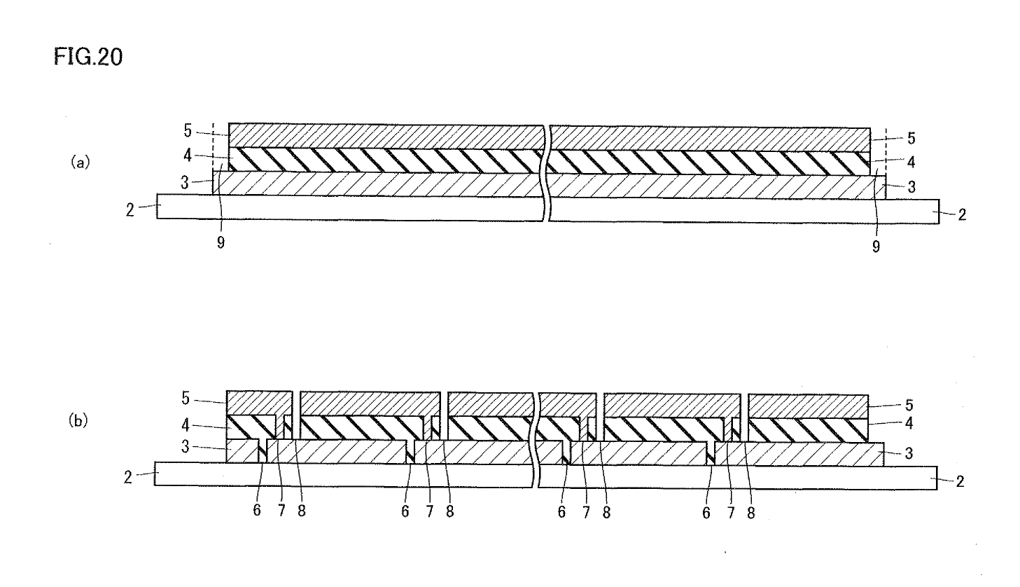

Next, towards a region located at an outer side of perimeter trench 9 formed at the neighborhood of respective side ends in the longitudinal direction of the separation trench, a laser beam (second laser beam) having a wavelength different from that of the first laser beam is directed from the side of transparent insulation substrate 2 in a direction orthogonal to the longitudinal direction of the separation trench for second laser beam radiation. Thus, transparent electrode layer 3, semiconductor photoelectric conversion layer 4 and back electrode layer 5 located at the outer side of perimeter trench 9 are removed in strips, as shown in FIG. 20(a).

In addition, towards a region located at an outer side of perimeter trench 9 formed at the neighborhood of one of the ends in the direction orthogonal to the longitudinal direction of the separation trench, the second laser beam is directed in the direction of the longitudinal direction of the separation trench from the side of transparent insulation substrate 2 for second laser beam radiation. Thus, the regions of transparent electrode layer 3, semiconductor photoelectric conversion layer 4, and back electrode layer 5 located at the outer side of perimeter trench 9 formed at the neighborhood of the end in the direction orthogonal to the longitudinal direction of the separation trench are removed, as shown in FIG. 20(b).

Further, the region of transparent electrode layer 3, semiconductor photoelectric conversion layer 4 and back electrode layer 5 located at the side end where perimeter trench 9 is not formed in the direction orthogonal to the longitudinal direction of separation trench are removed in strips by directing a second laser beam in the longitudinal direction of the separation trench from the side of transparent insulation substrate 2 for second laser beam radiation.

Subsequently, a current drawout electrode 10 extending in the longitudinal direction of the separation trench is formed at the surface of back electrode layer 5 at both side ends of the direction orthogonal to the longitudinal direction of the separation trench, as shown in FIG. 12(b).

Finally, an EVA sheet, for example, is provided on the surface of back electrode layer 5 after electrode 10 is provided, followed by providing a protection film formed of a 3-layer laminate film of PET/Al/PET on the EVA sheet. Thermal compression bonding is applied thereto. Thus, thin-film solar cell 1 having the structure shown in FIG. 11 is completed.

In the present embodiment, transparent electrode layer 3 protrudes in the direction orthogonal to the longitudinal direction of the separation trench, extending beyond semiconductor photoelectric conversion layer 4 and back electrode layer 5, as shown at the right side in FIG. 12(b). Since attachment of transparent electrode layer 3 caused by evaporation is suppressed at the end face of semiconductor photoelectric conversion layer 4 shown at the right side of FIG. 12(b), it is not necessary to form first separation trench 6 directed to ensuring insulation (first separation trench 6 at the right end in FIG. 2(b)), differing from the first embodiment.

Thus, thin-film solar cell 1 of the present embodiment is advantageous in that, in addition to the effect described in the first embodiment, the output can be further improved as compared to the thin-film solar cell of the first embodiment since the power generation region can be further increased than in the first embodiment.

A protruding length L3 of transparent electrode layer 3 in the direction orthogonal to the longitudinal direction of the separation trench shown in FIG. 12(b) is preferably greater than or equal to 100 μm and less than or equal to 1000 μm. The reason thereof is similar to that given above for the first embodiment.

As shown in FIG. 12(b), transparent electrode layer 3 requires to be protruding towards the negative electrode (right electrode 10 in FIG. 12(b)), and the configuration of transparent electrode layer 3 at the positive electrode side (left electrode 10 in FIG. 12(b)) is not particularly limited.

The remaining elements of the present embodiment are similar to those of the first embodiment

### EXAMPLE

### Example 1

As shown in FIGS. 3(a) and 3(b), a transparent insulation substrate 2 formed of a glass substrate was prepared, having a rectangular surface of 560 mm (width)×925 mm (length) with an SnO₂ transparent conductive layer 3 formed.

A YAG laser beam of the fundamental wave was directed from the side of transparent insulation substrate 2 in the longitudinal direction of the separation trench to remove transparent conductive layer 3 in stripes. Thus, fifty first separation trenches 6, each having a width of 0.08 mm, were formed, as shown in FIG. 4(b). First separation trenches 6 were formed such that the distance between adjacent first separation trenches 6 was equal (only in the power generation area). For transparent insulation substrate 2, ultrasonic cleaning was carried out by pure water. First separation trench 6 was not formed in the direction orthogonal to the longitudinal direction of the separation trench, as shown in FIG. 4(a).

Then, plasma CVD was employed to sequentially deposit a p layer formed of hydrogenated amorphous silicon type semiconductor (a-Si:H) doped with boron, an i layer formed of hydrogenated amorphous silicon type semiconductor (a-Si:H) that is undoped, and an n layer formed of hydrogenated microcrystalline silicon type semiconductor (μc-Si:H) doped with phosphorus, and also a p layer formed of hydrogenated microcrystalline silicon type semiconductor (μc-Si:H), an i layer formed of hydrogenated microcrystalline silicon type semiconductor (μc-Si:H), and an n layer formed, of hydrogenated microcrystalline silicon type semiconductor (μc-Si:H) in the cited order. Thus, semiconductor photoelectric conversion layer 4 was obtained, as shown in FIGS. 5(a) and 5(b).

A YAG laser beam of the second harmonic generation was directed from the side of transparent insulation substrate 2 in the longitudinal direction of the separation trench at an intensity that will not damage transparent electrode layer 3 to partially remove semiconductor photoelectric conversion layer 4 in stripes. Thus, contact lines 7 were formed, as shown in FIG. 6(b). Contact lines 7 were formed such that the distance between adjacent contact lines 7 was equal. Contact line 7 was not formed in the direction orthogonal to the longitudinal direction of the separation trench, as shown in FIG. 6(a).

Then, by sequentially depositing a transparent conductive film formed of ZnO and a metal thin film formed of silver by sputtering, back electrode layer 5 was obtained, as shown in FIGS. 7(a) and 7(b).

Next, by directing a YAG laser beam of the second harmonic generation in the longitudinal direction of the separation trench from the side of transparent insulation substrate 2 for radiation, semiconductor photoelectric conversion layer 4 and back electrode layer 5 were partially removed in stripes. Thus, second separation trenches 8 were formed, as shown in FIG. 8(b). Second separation trenches 8 were formed such that the distance between adjacent second separation trenches 8 was equal. Second separation trench 8 was not formed in the direction orthogonal to the longitudinal direction of the separation trench, as shown in FIG. 8(a).

By directing a YAG laser beam of the second harmonic generation in the direction orthogonal to the longitudinal direction of the separation trench from the side of transparent insulation substrate 2, the regions of semiconductor photoelectric conversion layer 4 and back electrode layer 5 located at the neighborhood of each side ends in the longitudinal direction of the separation trench were removed as a stripe to form perimeter trench 9 at the neighborhood of each side end in the longitudinal direction of the separation trench, as shown in FIG. 9(a). Perimeter trench 9 was not formed at the neighborhood of the end in the direction orthogonal to the longitudinal direction of the separation trench, as shown in FIG. 9(b).

By directing a YAG laser beam of the fundamental wave in the direction orthogonal to the longitudinal direction of the separation trench from the side of transparent insulation substrate 2 for radiation, transparent electrode layer 3, semiconductor photoelectric conversion layer 4 and back electrode layer 5 located at the outer side region of perimeter trench 9 were removed as a stripe, as shown in FIG. 10(a). The stripe had a width of 11 mm from the outer side.

Further, by directing a YAG laser beam of the fundamental wave in the longitudinal direction of the separation trench from the side of transparent insulation substrate 2, the region of transparent electrode layer 3, semiconductor photoelectric conversion layer 4 and back electrode layer 5 located at both side ends in the longitudinal direction of the separation trench were removed as a stripe, as shown in FIG. 10(b). The stripe had a width of 11 mm from the outer side.

Then, a bus bar electrode with a tin-silver-copper coat on copper foil, extending in the longitudinal direction of the separation trench, was formed as current drawout electrode 10 on the surface of back electrode layer 5 at either side end in the direction orthogonal to the longitudinal direction of the separation trench.

Then, an EVA sheet was provided on the surface of back electrode layer 5, followed by providing a protection film formed of a 3-layer laminate film of PET/Al/PET on the EVA sheet. Thermal compression bonding was applied thereto to produce a thin-film solar cell of Example 1, having a surface shown in FIG. 1 and a cross section shown in FIGS. 2(a) and 2(b). The protruding lengths L1 and L2 of transparent electrode layer 3 of the thin-film solar cell of Example 1 shown in FIG. 2(b) were measured. Both protruding lengths L1 and L2 were 200 μm.

The output of the thin-film solar cell of Example 1 was measured through a solar simulator. The results are shown in Table 1. It is appreciated from Table 1 that the output of the thin-film solar cell of Example 1 was 52 W.

### Example 2

As shown in FIGS. 13(a) and 13(b), a transparent insulation substrate 2 formed of a glass substrate was prepared, having a rectangular surface of 560 mm (width)×925 mm (length) with an SnO₂ transparent conductive layer 3 formed.

A YAG laser beam of the fundamental wave was directed from the side of transparent insulation substrate 2 in the longitudinal direction of the separation trench to remove transparent conductive layer 3 in stripes. Thus, fifty first separation trenches 6, each having a width of 0.08 mm, were formed, as shown in FIG. 14(b). First separation trenches 6 were formed such that the distance between adjacent first separation trenches 6 was equal (only in the power generation area). For transparent insulation substrate 2, ultrasonic cleaning was carried out by pure water. First separation trench 6 was not formed in the direction orthogonal to the longitudinal direction of the separation trench, as shown in FIG. 14(a).

Then, plasma CVD was employed to sequentially deposit a p layer formed of hydrogenated amorphous silicon type semiconductor (a-Si:H) doped with boron, an i layer formed of hydrogenated amorphous silicon type semiconductor (a-Si:H) that is undoped, and an n layer formed of hydrogenated microcrystalline silicon type semiconductor (μc-Si:H) doped with phosphorus, and also a p layer formed of hydrogenated microcrystalline silicon type semiconductor (μc-Si:H), an i layer formed of hydrogenated microcrystalline silicon type semiconductor (μc-Si:H), and an n layer formed of hydrogenated microcrystalline silicon type semiconductor (μc-Si:H) in the cited order. Thus, semiconductor photoelectric conversion layer 4 was obtained, as shown in FIGS. 15(a) and 15(b).

A YAG laser beam of the second harmonic generation was directed from the side of transparent insulation substrate 2 in the longitudinal direction of the separation trench at an intensity that will not damage transparent electrode layer 3 to partially remove semiconductor photoelectric conversion layer 4 in stripes. Thus, contact lines 7 were formed, as shown in FIG. 16(b). Contact lines 7 were formed such that the distance between adjacent contact lines 7 was equal. Contact line 7 was not formed in the direction orthogonal to the longitudinal direction of the separation trench, as shown in FIG. 16(a).

Then, by sequentially depositing a transparent conductive film formed of ZnO and a metal thin film formed of silver by sputtering, back electrode layer 5 was obtained, as shown in FIGS. 17(a) and 17(b).

Next, by directing a YAG laser beam of the second harmonic generation in the longitudinal direction of the separation trench from the side of transparent insulation substrate 2 for radiation, semiconductor photoelectric conversion layer 4 and back electrode layer 5 were partially removed in stripes. Thus, second separation trenches 8 were formed, as shown in FIG. 18(b). Second separation trenches 8 were formed such that the distance between adjacent second separation trenches 8 was equal. Second separation trench 8 was not formed in the direction orthogonal to the longitudinal direction of the separation trench, as shown in FIG. 18(a).

By directing a YAG laser beam of the second harmonic generation in the direction orthogonal to the longitudinal direction of the separation trench from the side of transparent insulation substrate 2, the regions of semiconductor photoelectric conversion layer 4 and back electrode layer 5 located at the neighborhood of each side ends in the longitudinal direction of the separation trench were removed as a stripe to form perimeter trench 9 at the neighborhood of each side end of the longitudinal direction of the separation trench, as shown in FIG. 19(a).

Subsequently, by directing a YAG laser beam of the second harmonic generation in the longitudinal direction of the separation trench from the side of transparent insulation substrate 2, the regions of semiconductor photoelectric conversion layer 4 and back electrode layer 5 located at the neighborhood of one side end in the longitudinal direction of the separation trench were removed as a stripe to form perimeter trench 9 at the neighborhood of one end in the direction orthogonal to the longitudinal direction of the separation trench, as shown in FIG. 19(b).

Then, by directing a YAG laser beam of the fundamental wave in the direction orthogonal to the longitudinal direction of the separation trench from the side of transparent insulation substrate 2 for radiation, transparent electrode layer 3, semiconductor photoelectric conversion layer 4 and back electrode layer 5 located at the outer side region of perimeter trench 9 were removed as a stripe, as shown in FIG. 20(a). The stripe had a width of 11 mm from the outer side.

Further, by directing a YAG laser beam of the fundamental wave in the longitudinal direction of the separation trench from the side of transparent insulation substrate 2 for radiation, transparent electrode layer 3, semiconductor photoelectric conversion layer 4 and back electrode layer 5 located at the outer side region of perimeter trench 9 were removed as a stripe, as shown at the right side of FIG. 20(b). The stripe had a width of 11 mm from the outer side.

In addition, by directing a YAG laser beam of the fundamental wave in the longitudinal direction of the separation trench from the side of transparent insulation substrate 2, the region of transparent electrode layer 3, semiconductor photoelectric conversion layer 4 and back electrode layer 5 located at the side where perimeter trench 9 is not formed was removed as a stripe, as shown at the left side of FIG. 20(b). The stripe had a width of 11 mm from the outer side.

Then, a bus bar electrode with a tin-silver-copper coat on copper foil, extending in the longitudinal direction of the separation trench, was formed as current drawout electrode 10 on the surface of back electrode layer 5 at either side end in the direction orthogonal to the longitudinal direction of the separation trench.

Thereafter, an EVA sheet was provided on the surface of back electrode layer 5, followed by providing a protection film formed of a 3-layer laminate film of PET/Al/PET on the EVA sheet. Thermal compression bonding was applied thereto to produce a thin-film solar cell of Example 2, having a surface shown in FIG. 11 and cross sections shown in FIGS. 12(a) and 12(b). The protruding lengths L1 and L2 of transparent electrode layer 3 of the thin-film solar cell of Example 2 shown in FIG. 12(b) were measured. Both protruding lengths L1 and L2 were 200 μm.

The output of the thin-film solar cell of Example 2 was measured through a solar simulator. The results are shown in Table 1. It is appreciated from Table 1 that the output of the thin-film solar cell of Example 2 was 52.4 W.

### Comparative Example 1

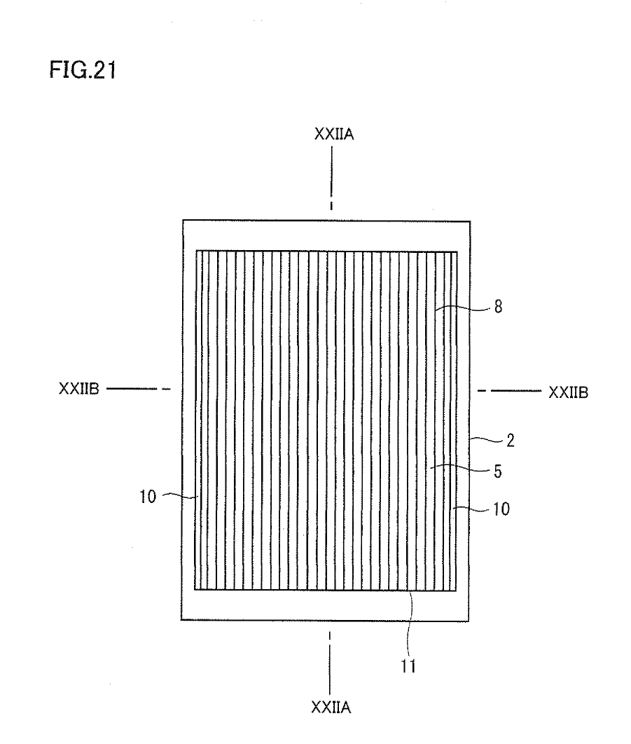

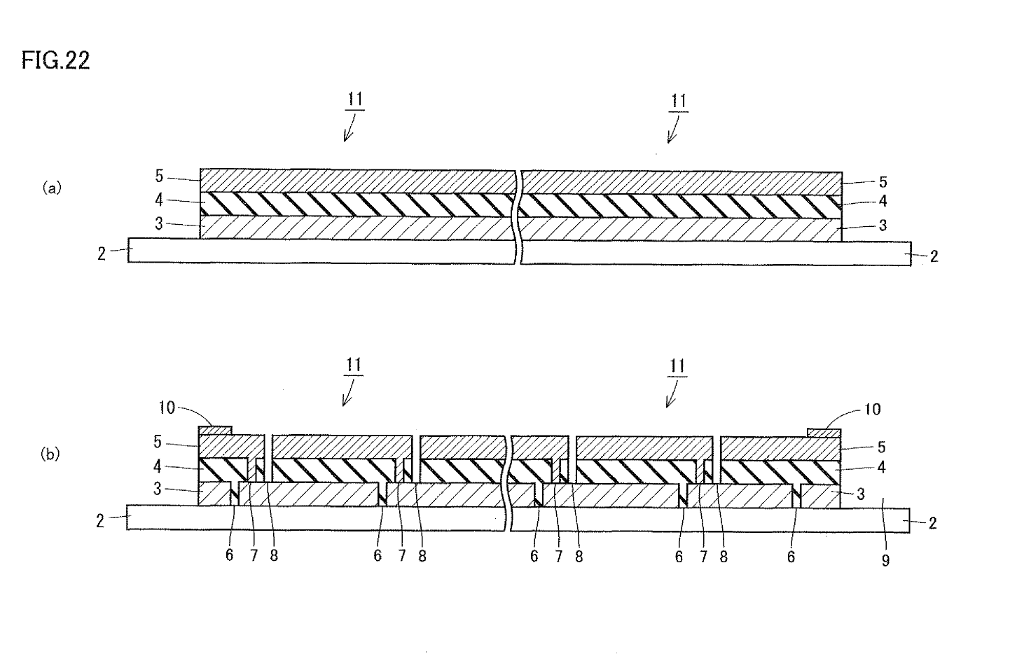

A thin-film solar cell of Comparative Example 1 having the surface shown in FIG. 21 and cross sections shown in FIGS. 22(a) and 22(b) was produced. The thin-film solar cell of Comparative Example 1 is characterized in that transparent electrode layer 3 does not extend outward beyond semiconductor photoelectric conversion layer 4 and back electrode layer 5 at the perimeter region. FIG. 22(a) is based on a schematic cross section taken along line XXIIA-XXIIA of FIG. 21, and FIG. 22(b) is based on a schematic cross section taken along XXIIB-XXIIB of FIG. 21.

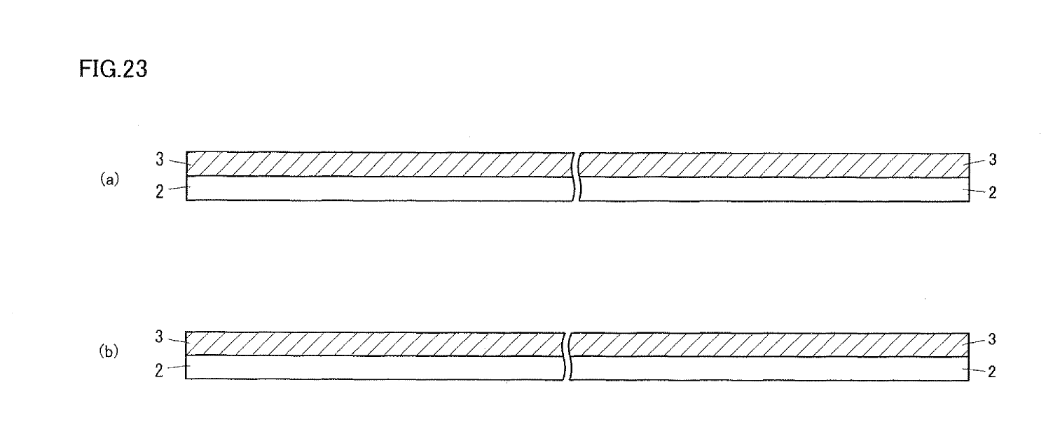

A method of fabricating the thin-film solar cell of Comparative Example 1 will be described hereinafter with reference to the schematic sectional views of FIGS. 23-29. In FIGS. 23-29, (a) corresponds to a cross section taken along the direction of XXIIA-XXIIA (longitudinal direction of separation trench) of FIG. 21, and (b) corresponds to a cross section taken along the direction of XXIIB-XXIIB (direction orthogonal to the longitudinal direction of separation trench) of FIG. 21.

As shown in FIGS. 23(a) and 23(b), a transparent insulation substrate 2 formed of a glass substrate was prepared, having a rectangular surface of 560 mm (width)×925 mm (length) with an SnO₂ transparent conductive layer 3 formed.

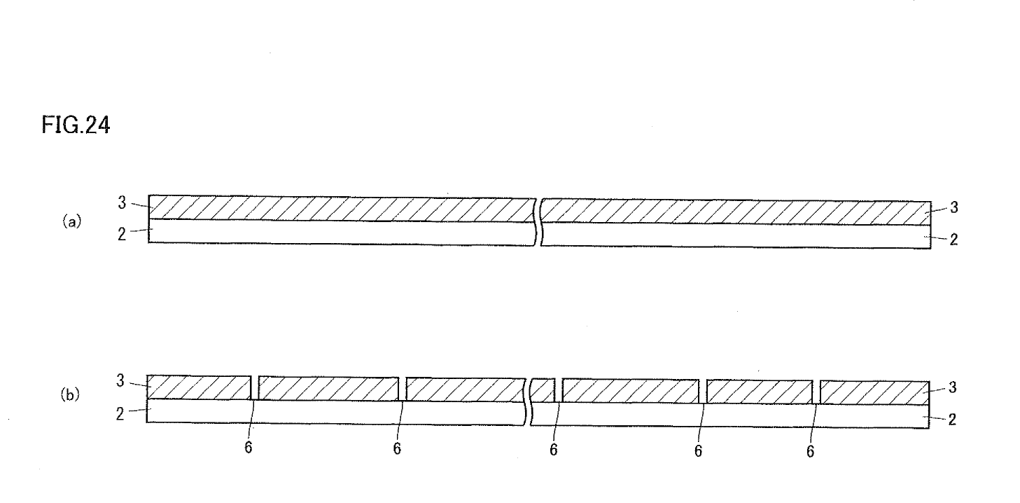

A YAG laser beam of the fundamental wave was directed from the side of transparent insulation substrate 2 in the longitudinal direction of the separation trench to remove transparent conductive layer 3 in stripes. Thus, fifty first separation trenches 6, each having a width of 0.08 mm, were formed, as shown in FIG. 24(b). First separation trenches 6 were formed such that the distance between adjacent first separation trenches 6 was equal (only in the power generation area). For transparent insulation substrate 2, ultrasonic cleaning was carried out by pure water. Since a laser beam was not directed in a direction orthogonal to the longitudinal direction of the separation trench, first separation trench 6 was not formed in the direction orthogonal to the longitudinal direction of the separation trench, as shown in FIG. 24(a).

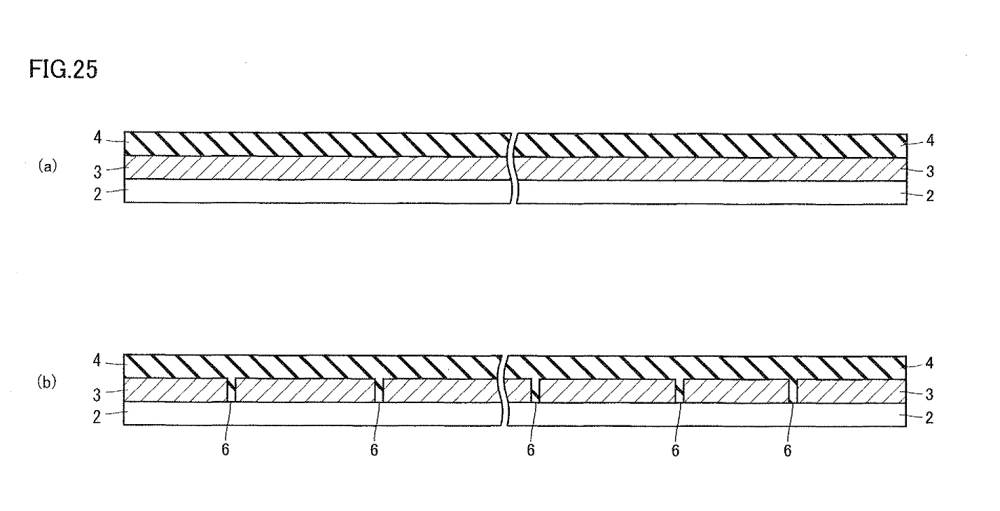

Then, plasma CVD was employed to sequentially deposit a p layer formed of hydrogenated amorphous silicon type semiconductor (a-Si:H) doped with boron, an i layer formed of hydrogenated amorphous silicon type semiconductor (a-Si:H) that is undoped, and an n layer formed of hydrogenated microcrystalline silicon type semiconductor (μc-Si:H) doped with phosphorus, and also a p layer formed of hydrogenated microcrystalline silicon type semiconductor (μc-Si:H), an i layer formed of hydrogenated microcrystalline silicon type semiconductor (μc-Si:H), and an n layer formed of hydrogenated microcrystalline silicon type semiconductor (μc-Si:H) in the cited order. Thus, semiconductor photoelectric conversion layer 4 was obtained, as shown in FIGS. 25(a) and 25(b).

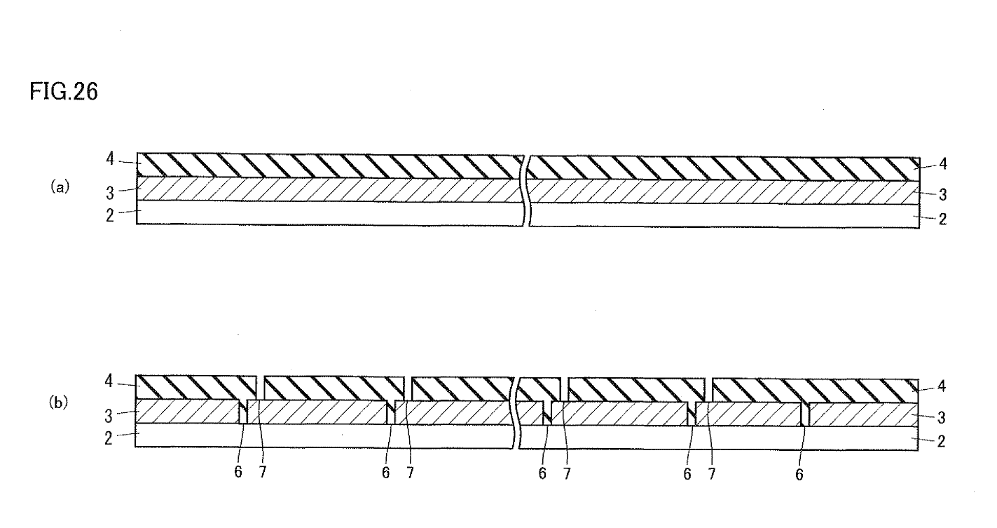

Next, a YAG laser beam of the second harmonic generation was directed from the side of transparent insulation substrate 2 in the longitudinal direction of the separation trench at an intensity that will not damage transparent electrode layer 3 to partially remove semiconductor photoelectric conversion layer 4 in stripes. Thus, contact lines 7 were formed, as shown in FIG. 26(b). Contact lines 7 were formed such that the distance between adjacent contact lines 7 was equal. Contact line 7 was not formed in the direction orthogonal to the longitudinal direction of the separation trench, as shown in FIG. 26(a), since a laser beam was not directed in a direction orthogonal to the longitudinal direction of the separation trench.

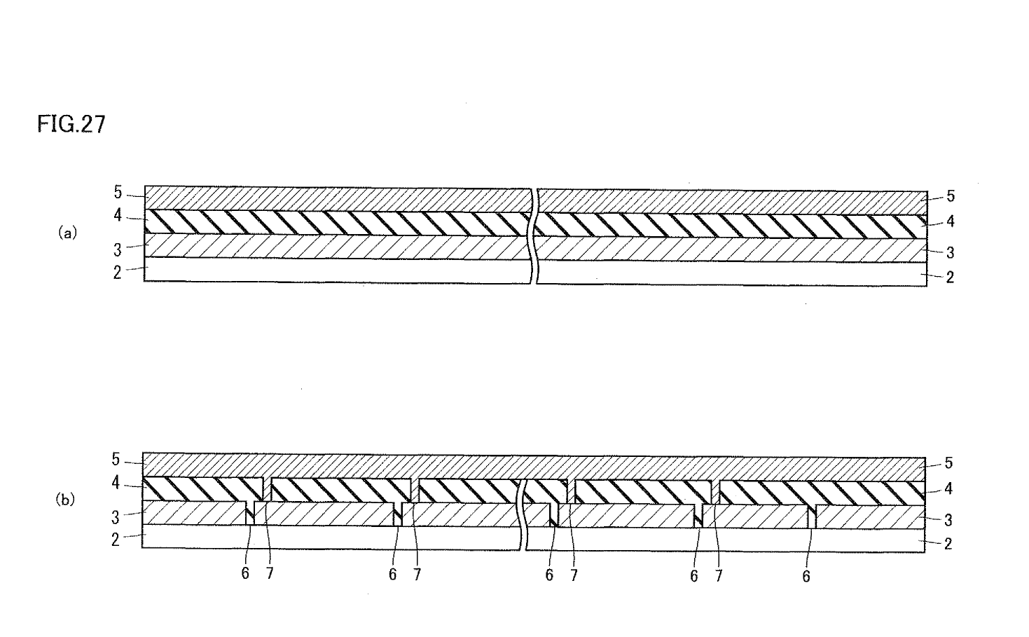

Then, by sequentially depositing a transparent conductive film formed of ZnO and a metal thin film formed of silver by sputtering, back electrode layer 5 was obtained, as shown in FIGS. 27(a) and 27(b).

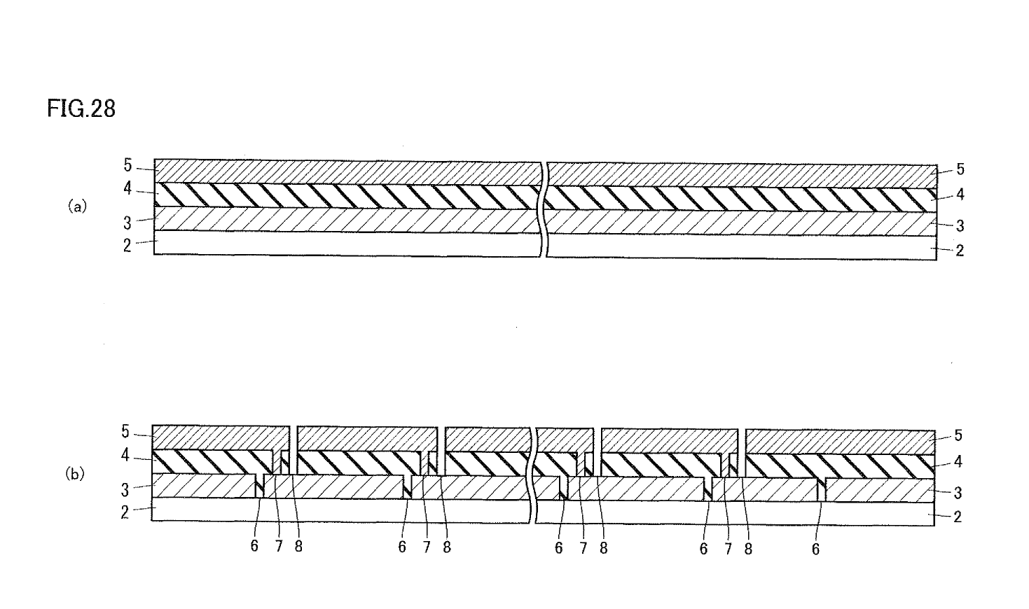

Next, by directing a YAG laser beam of the second harmonic generation in the longitudinal direction of the separation trench from the side of transparent insulation substrate 2 for radiation, semiconductor photoelectric conversion layer 4 and back electrode layer 5 were partially removed in stripes. Thus, second separation trenches 8 were formed, as shown in FIG. 28(b). Second separation trenches 8 were formed such that the distance between adjacent second separation trenches 8 was equal. Since a laser beam was not directed in a direction orthogonal to the longitudinal direction of the separation trench, second separation trench 8 was not formed in the direction orthogonal to the longitudinal direction of the separation trench, as shown in FIG. 28(a).

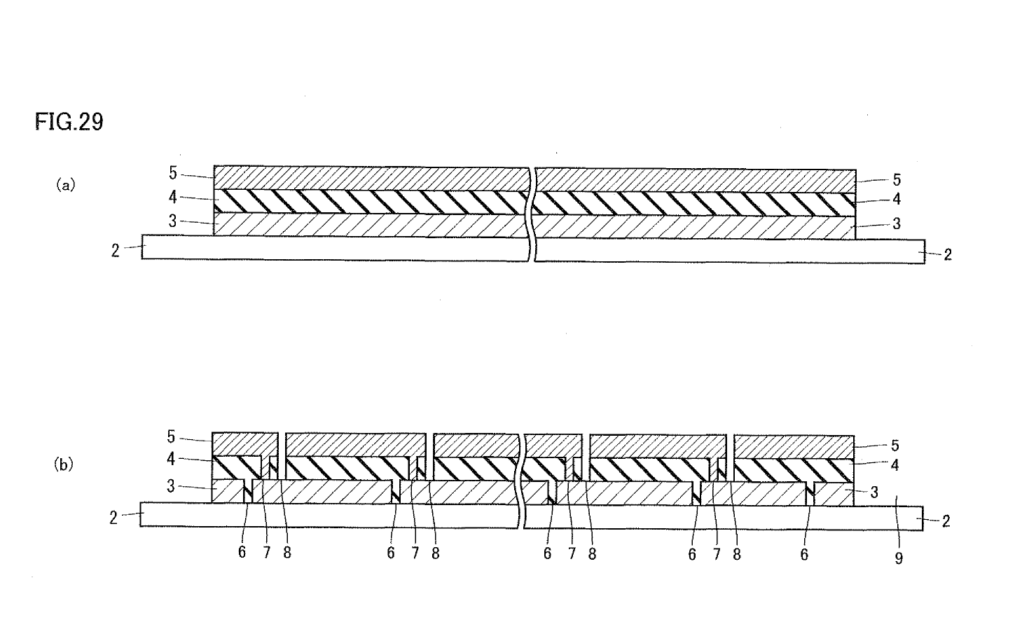

By directing a YAG laser beam of the fundamental wave in the longitudinal direction and in the direction orthogonal to the longitudinal direction of the separation trench from the side of transparent insulation substrate 2 for radiation, the perimeter region of transparent electrode layer 3, semiconductor photoelectric conversion layer 4 and back electrode layer 5 were removed along the entire circumference by a length of 11 mm from the outer side, as shown in FIGS. 29(a) and 29(b).

Further, a bus bar electrode with a tin-silver-copper coat on copper foil, extending in the longitudinal direction of the separation trench, was formed as current drawout electrode 10 on the surface of back electrode layer 5 at either side end of the direction orthogonal to the longitudinal direction of the separation trench.

Then, an EVA sheet was provided on the surface of back electrode layer 5, followed by providing a protection film formed of a 3-layer laminate film of PET/Al/PET on the EVA sheet. Thermal compression bonding was applied thereto to produce a thin-film solar cell of Comparative Example 1, having a surface shown in FIG. 21 and cross sections shown in FIGS. 22(a) and 22(b).

The output of the thin-film solar cell of Comparative Example 1 was measured through a solar simulator. The results are shown in Table 1. It is appreciated from Table 1 that the output of the thin-film solar cell of Comparative Example 1 was 48.66 W. In the thin-film solar cell of Comparative Example 1, the property of luminance dependency was degraded.

### Comparative Example 2

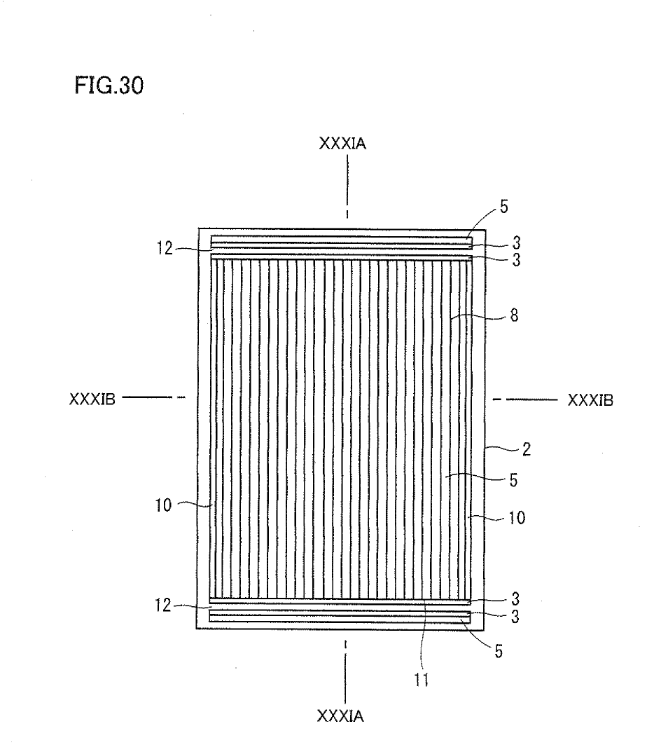

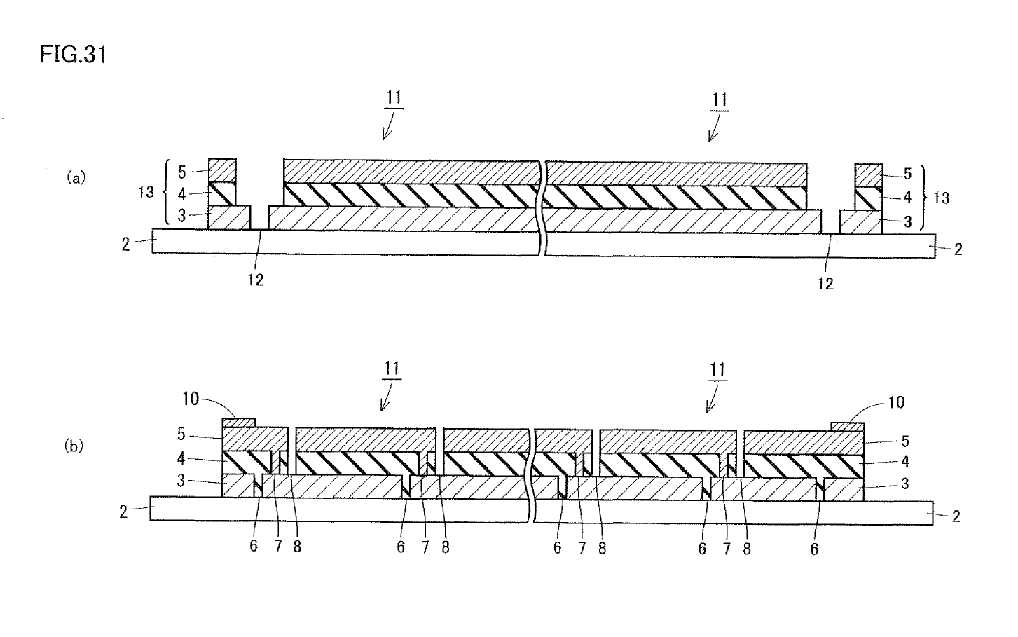

A thin-film solar cell of Comparative Example 2 having a surface of FIG. 30 and cross sections of FIGS. 31(a) and 31(b) was produced. The thin-film solar cell of Comparative Example 2 is characterized in that a laminate 13 for scratch protection is formed by polishing at the neighborhood of each side ends in the longitudinal direction of the separation trench. FIG. 31(a) is based on a schematic cross section taken along XXXIA-XXXIA of FIG. 30, and FIG. 31(b) is based on a schematic cross section taken along XXXIB-XXXIB of FIG. 30.

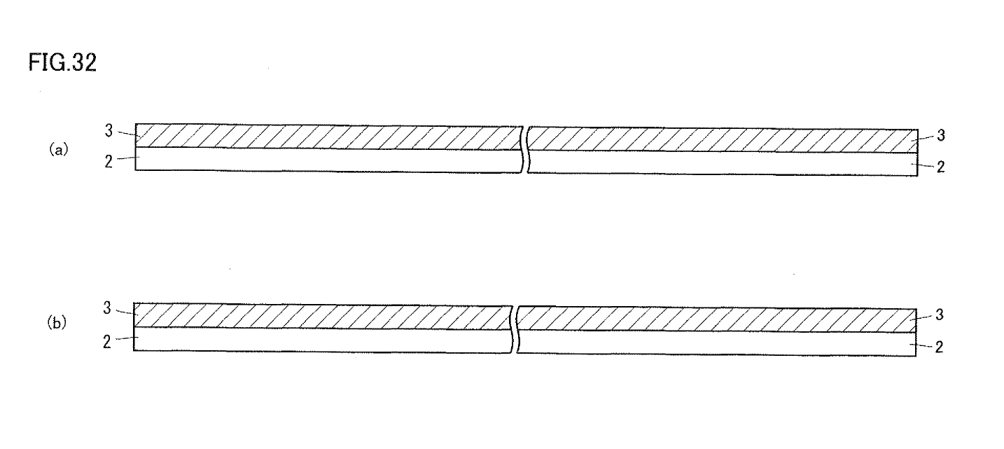

A method of fabricating the thin-film solar cell of Comparative Example 2 will be described hereinafter with reference to the schematic sectional views of FIGS. 32-39. In FIGS. 32-39, (a) corresponds to a cross section taken along the direction of XXXIA-XXXIA (longitudinal direction of separation trench) of FIG. 30, and (b) corresponds to a cross section taken along the direction of XXXIB-XXXIB (direction orthogonal to the longitudinal direction of separation trench) of FIG. 30.

As shown in FIGS. 32(a) and 32(b), a transparent insulation substrate 2 formed of a class substrate was prepared, having a rectangular surface of 560 mm (width)×925 mm (length) with an SnO₂ transparent conductive layer 3 formed.

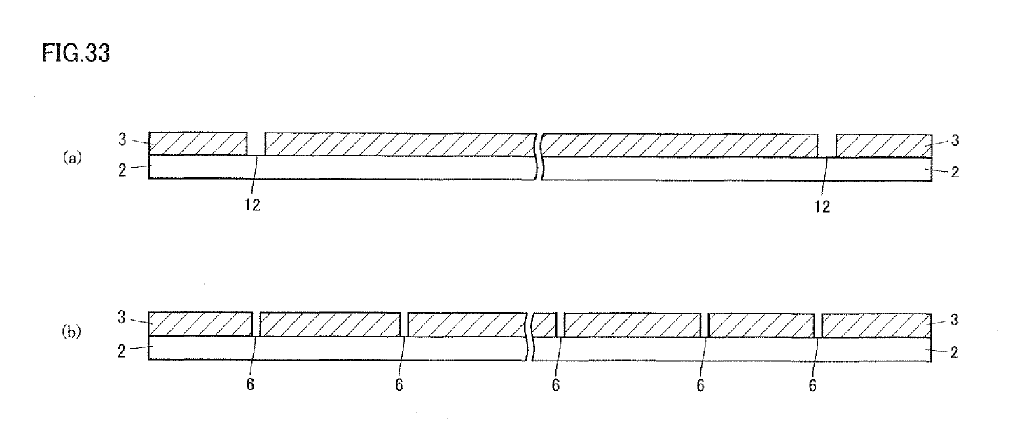

A YAG laser beam of the fundamental wave was directed from the side of transparent insulation substrate 2 in the longitudinal direction of the separation trench to remove transparent conductive layer 3 in stripes. Thus, fifty first separation trenches 6, each having a width of 0.08 mm, were formed, as shown in FIG. 33(b). First separation trenches 6 were formed such that the distance between adjacent first separation trenches 6 was equal (only in the power generation area).

By directing a YAG laser beam of the fundamental wave in the direction orthogonal to the longitudinal direction of the separation trench from the side of transparent insulation substrate 2, the region of transparent conductive layer 3 located at the neighborhood of each side end in the longitudinal direction of the separation trench was removed in stripes to form perimeter trench 12, as shown in FIG. 33(a).

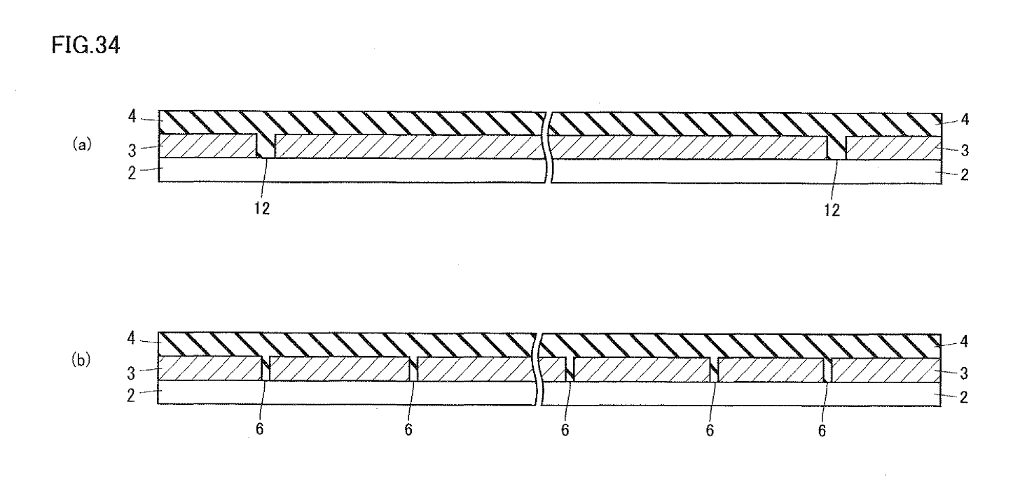

Then, plasma CVD was employed to sequentially deposit a p layer formed of hydrogenated amorphous silicon type semiconductor (a-Si:H) doped with boron, an i layer formed of hydrogenated amorphous silicon type semiconductor (a-Si:H) that is undoped, and an n layer formed of hydrogenated microcrystalline silicon type semiconductor (μc-Si:H) doped with phosphorus, and also a p layer formed of hydrogenated microcrystalline silicon type semiconductor (μc Si:H), an i layer formed of hydrogenated microcrystalline silicon type semiconductor (μc-Si:H), and an n layer formed of hydrogenated microcrystalline silicon type semiconductor (μc-Si:H) in the cited order. Thus, semiconductor photoelectric conversion layer 4 was obtained, as shown in FIGS. 34(a) and 34(b).

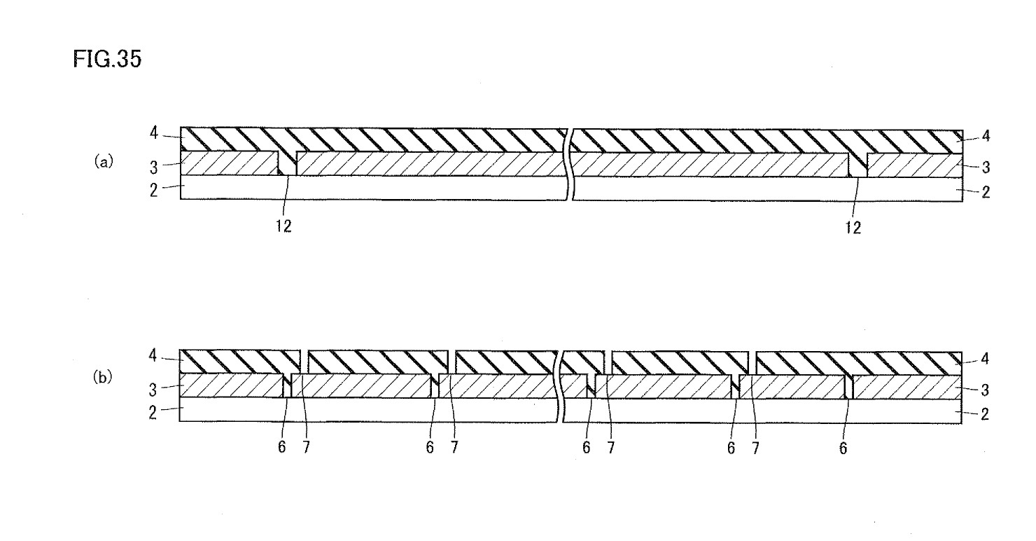

Next, a YAG laser beam of the second harmonic generation was directed from the side of transparent insulation substrate 2 in the longitudinal direction of the separation trench at an intensity that will not damage transparent electrode layer 3 to partially remove semiconductor photoelectric conversion layer 4 in stripes. Thus, contact lines 7 were formed, as shown in FIG. 35(b). Contact lines 7 were formed such that the distance between adjacent contact lines 7 was equal. Since a laser beam was not directed in a direction orthogonal to the longitudinal direction of the separation trench, contact line 7 was not formed in the direction orthogonal to the longitudinal direction of the separation trench, as shown in FIG. 35(a).

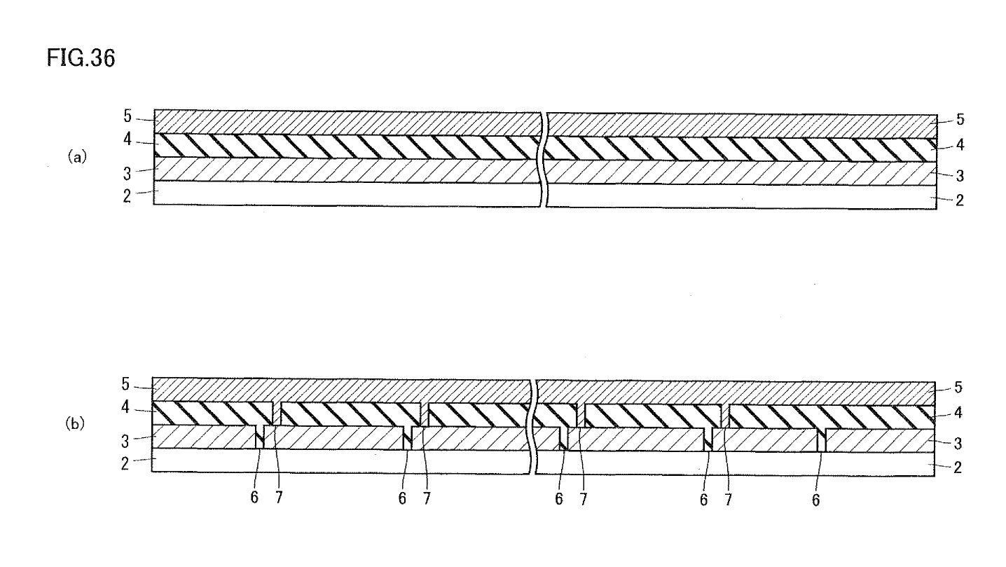

Then, by sequentially depositing a transparent conductive film formed of ZnO and a metal thin film formed of silver by sputtering, back electrode layer 5 was obtained, as shown in FIGS. 36(a) and 36(b).

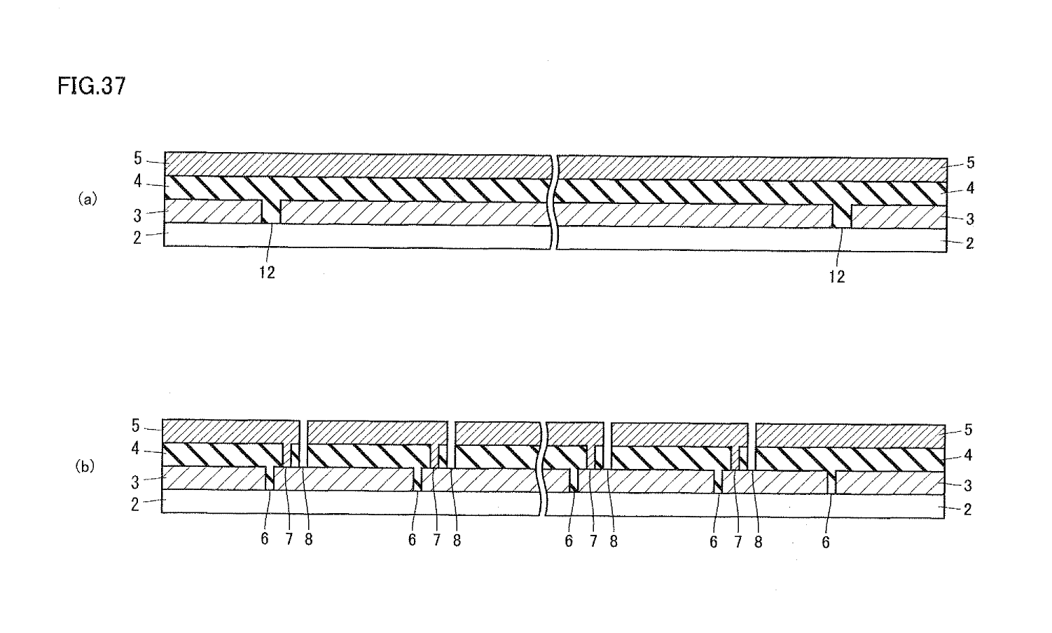

Next, by directing a YAG laser beam of the second harmonic generation in the longitudinal direction of the separation trench from the side of transparent insulation substrate 2 for radiation, semiconductor photoelectric conversion layer 4 and back electrode layer 5 were partially removed in stripes. Thus, second separation trenches 8 were formed, as shown in FIG. 37(b). Second separation trenches 8 were formed such that the distance between adjacent second separation trenches 8 was equal. Since a laser beam was not directed in a direction orthogonal to the longitudinal direction of the separation trench, second separation trench 8 was not formed in the direction orthogonal to the longitudinal direction of the separation trench, as shown in FIG. 37(a).

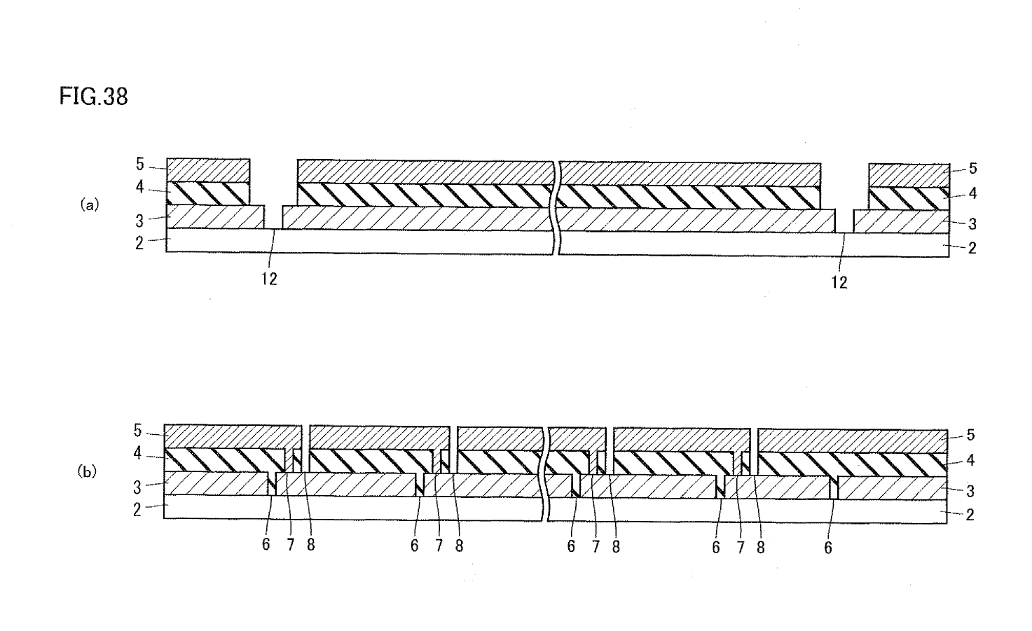

By directing a YAG laser beam of the second harmonic generation in the direction orthogonal to the longitudinal direction of the separation trench from the side of transparent insulation substrate 2, the regions of transparent electrode layer 3, semiconductor photoelectric conversion layer 4 and back electrode layer 5 located at the neighborhood of each side end in the longitudinal direction of the separation trench were removed, as shown in FIG. 38(a). The YAG laser beam of the second harmonic generation was directed with a width larger than that of perimeter trench 12, so as to include the formation region of perimeter trench 12. Since a YAG laser beam of a second harmonic generation was not directed in a direction orthogonal to the longitudinal direction of the separation trench, transparent electrode layer 3, semiconductor photoelectric conversion layer 4 and back electrode layer 5 were not removed in the direction orthogonal to the longitudinal direction of the separation trench, as shown in FIG. 38(b).

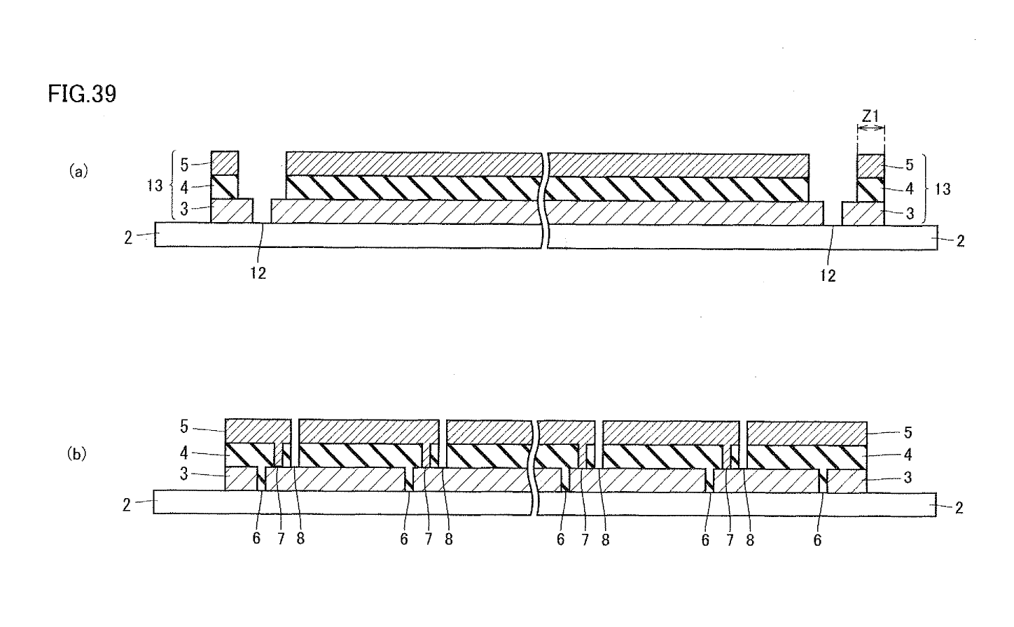

Then, transparent electrode layer 3, semiconductor photoelectric conversion layer 4 and back electrode layer 5 located at the outer side region of perimeter trench 12 were removed along the entire circumference by polishing, and the polished region was rinsed. Accordingly, the perimeter region of transparent electrode layer 3, semiconductor photoelectric conversion layer 4 and back electrode layer 5 were removed along the entire circumference by a length of 11 mm from the outer side, as shown in FIGS. 39(a) and 39(b). At this stage, laminate 13 is formed at the outer side of perimeter trench 12, as shown in FIG. 39(a). A width Z1 of laminate 13 was approximately 3 mm.

Then, a bus bar electrode with a tin-silver-copper coat on copper foil, extending in the longitudinal direction of the separation trench, was formed as current drawout electrode 10 on the surface of back electrode layer 5 at either side end in the direction orthogonal to the longitudinal direction of the separation trench.

Thereafter, an EVA sheet was provided on the surface of back electrode layer 5, followed by providing a protection film formed of a 3-layer laminate film of PET/Al/PET on the EVA sheet. Thermal compression bonding was applied thereto to produce a thin-film solar cell of Comparative Example 2, having a surface shown in FIG. 30 and cross sections shown in FIGS. 31(a) and 31(b).

The output of the thin-film solar cell of Comparative Example 2 was measured through a solar simulator. The results are shown in Table 1. It is appreciated from Table 1 that the output of the thin-film solar cell of Comparative Example 2 was 51.6 W.

TABLE 1

| | Output (W) |
|---|---|
| Example 1 | 52 |
| Example 2 | 52.4 |
| Comparative | 48.66 |
| Example 1 | |
| Comparative | 51.6 |
| Example 2 | |

It is appreciated from the results shown in Table 1 that the thin-film solar cells of Examples 1 and 2 were improved in output, as compared to thin-film solar cells of Comparative Examples 1 and 2. A possible consideration is that the ratio of the formation region of cell-integrated region 11 to the surface of transparent insulation substrate 2 is increased in the thin-film solar cells of Examples 1 and 2, allowing a larger power generation region, as compared to the thin-film solar cells of Comparative Examples 1 and 2.

Further, the thin-film solar cell of Example 2 had the power output improved, as compared to the thin-film solar cell of Example 1, as shown in Table 1. This is attributed to a larger power generation region in the thin-film solar cell of Example 2, as compared to the thin-film solar cell of Example 1, since it is not necessary to form a first separation trench 6 (first separation trench 6 at the right side in FIG. 2(b)) to reduce leakage at the negative electrode portion.

It should be understood that the embodiments and examples disclosed herein are illustrative and non-restrictive in every respect. The scope of the present invention is defined by the terms of the claims, rather than the description above, and is intended to include any modification within the scope and meaning equivalent to the terms of the claims.

### INDUSTRIAL APPLICABILITY

According to the present invention, there can be provided a thin-film solar cell allowing the fabrication cost to be reduced and the output improved, and a fabrication method of the thin-film solar cell.

1-7. (canceled)

8. A thin-film solar cell comprising:
a transparent insulation substrate,
a transparent electrode layer, a semiconductor photoelectric conversion layer, and a back electrode layer sequentially stacked on said transparent insulation substrate, and
a separation trench separating at least said back electrode layer,
said transparent electrode layer protruding in a longitudinal direction of said separation trench, extending beyond said semiconductor photoelectric conversion layer and said back electrode layer.

9. The thin-film solar cell according to claim 8, wherein a protruding length of said transparent electrode layer is greater than or equal to 100 μm and less than or equal to 1000 μm.

10. The thin-film solar cell according to claim 8, wherein said transparent electrode layer protrudes in a direction orthogonal to the longitudinal direction of said separation trench, extending beyond said semiconductor photoelectric conversion layer and said back electrode layer.

11. The thin-film solar cell according to claim 10, wherein a current drawout electrode is formed at said back electrode layer located at an end of a direction orthogonal to the longitudinal direction of said separation trench.

12. A method of fabricating a thin-film solar cell defined in claim 8, comprising the steps of:
stacking a transparent electrode layer on a transparent insulation substrate,
stacking a semiconductor photoelectric conversion layer on said transparent electrode layer,
stacking a back electrode layer on said semiconductor photoelectric conversion layer,
forming a separation trench separating at least said back electrode layer,
directing a first laser beam in a direction orthogonal to the longitudinal direction of said separation trench to remove the semiconductor photoelectric conversion layer and back electrode layer located at a radiation region by said first laser beam, and
directing a second laser beam to a region further outer than the radiation region by said first laser beam in the longitudinal direction of said separation trench to remove the transparent electrode layer, semiconductor photoelectric conversion layer and back electrode layer located at a radiation region by said second laser beam.

13. The method of fabricating a thin-film solar cell according to claim 12, wherein said first laser beam includes one of a YAG laser beam and YVO₄ laser beam having a second harmonic generation.

14. The method of fabricating a thin-film solar cell according to claim 12, wherein said second laser beam includes one of a YAG laser beam and YVO₄ laser beam having a fundamental wave.

15. A thin-film solar cell comprising:
a transparent insulation substrate,
a transparent electrode layer, a semiconductor photoelectric conversion layer, and a back electrode layer sequentially stacked on said transparent insulation substrate and
a separation trench separating at least said back electrode layer,
said transparent electrode layer protruding in a longitudinal direction of said separation trench, extending beyond said semiconductor photoelectric conversion layer and said back electrode layer, and
said transparent electrode layer, said semiconductor photoelectric conversion layer, and said back electrode layer are removed in the outside of said transparent electrode layer protruding in a longitudinal direction of said separation trench.
